(19) United States
(12) Patent Application Publication
(10) Pub. No.: US 2002/0038791 A1
(43) Pub. Date: Apr. 4, 2002

(54) Plasma processing method and apparatus

(76) Inventors: Tomohiro Okumura, Kadoma-shi (JP); Yukihiro Maegawa, Ibaraki-shi (JP); Izuru Matsuda, Ibaraki-shi (JP); Takayuki Kai, Katano-shi (JP)

Correspondence Address: WENDEROTH, LIND & PONACK, L.L.P., 2033 K STREET N. W., SUITE 800, WASHINGTON, DC, 20006-1021, US

(21) Appl. No.: 09/968,810

(22) Filed: Oct. 3, 2001

(30) Foreign Application Priority Data
Oct. 3, 2000 (JP) 2000-303334
Apr. 4, 2001 (JP) 2001-105442

(51) Int. Cl. C23F 1/02; C23C 14/00; C23C 16/00

(52) U.S. Cl. 216/71; 204/298.06; 118/723 I; 118/723 IR; 118/723 AN; 156/345; 216/68; 216/69; 427/569; 204/192.1

(57) ABSTRACT

While interior of a vacuum chamber is maintained to a specified pressure by introducing a specified gas from a gas supply unit into the vacuum chamber and simultaneously performing exhaustion by a pump as an exhauster, a high-frequency power of 100 MHz is supplied by an antenna use high-frequency power supply to an antenna provided so as to project into the vacuum chamber, by which plasma is generated in the vacuum chamber. The vacuum chamber grounded, and separated into a region on one side on which the substrate is present and a region on the other side on which the substrate is absent by a punching metal plate nearly all the peripheral portion of which is grounded.

### BACKGROUND OF THE INVENTION

The present invention relates to a plasma processing method and apparatus to be used for manufacturing semiconductors or other electronic devices and micromachines.

In the manufacture of semiconductors or other electronic devices and micromachines, thin-film processing techniques using plasma processing have been becoming increasingly important in recent years.

As an example of conventional plasma processing methods, plasma processing using a patch-antenna type plasma source is described below with reference to FIG. 9. Referring to FIG. 9, while interior of a vacuum chamber 1 is maintained to a specified pressure by introducing a specified gas from a gas supply unit 2 into the vacuum chamber 1 and simultaneously performing exhaustion by a turbo-molecular pump 3 as an exhauster, a high-frequency power of 100 MHz is supplied by an antenna use high-frequency power supply 4 to an antenna 5 provided so as to project into the vacuum chamber 1. Then, plasma is generated in the vacuum chamber 1, allowing plasma processing to be carried out with a substrate 7 placed on a substrate electrode 6. There is also provided a substrate-electrode use high-frequency power supply 8 for supplying high-frequency power to the substrate electrode 6, making it possible to control ion energy that reaches the substrate 7. The high-frequency voltage supplied to the antenna 5 is delivered to a proximity to the center of the antenna 5 by a feed bar 9. A plurality of sites of the antenna 5 other than its center and peripheries, and a face 1A of the vacuum chamber 1 opposite to the substrate 7 are short-circuited by short pins 10. A dielectric plate 11 is sandwiched between the antenna 5 and the vacuum chamber 1, and the feed bar 9 and the short pins 10 serve to connect the antenna 5 and the antenna use high-frequency power supply 4 to each other, and the antenna 5 and the vacuum chamber 1 to each other via through holes provided in the dielectric plate 11. Also, surfaces of the antenna 5 are covered with an insulating cover 12. Further, a plasma trap 15 is provided so as to comprise a groove-shaped space between the dielectric plate 11 and a dielectric ring 13 provided at a peripheral portion of the dielectric plate 11, and a groove-shaped space between the antenna 5 and a conductor ring 14 provided at a peripheral portion of the antenna 5. The substrate electrode 6 is fixed to the vacuum chamber 1 with four pillars 19 arranged at equal intervals.

The turbo-molecular pump 3 and an exhaust port 16 of the vacuum chamber 1 are disposed just under the substrate electrode 6, and a pressure-regulating valve 17 for controlling the vacuum chamber 1 to a specified pressure is an up-and-down valve disposed directly under the substrate electrode 6 and just over the turbo-molecular pump 3. Also, an inner chamber-forming member 18 covers the inner wall surface of the vacuum chamber 1, thereby preventing the vacuum chamber 1 from being contaminated by plasma processing. After a specified number of substrates 7 have been processed, the contaminated inner chamber-forming member 18 is replaced with a rotation component, thus considerations being given so that the maintenance work can promptly be carried out.

In the plasma processing described in the above prior-art example, however, there is an issue that plasma may spread to downstream of the substrate electrode 6 (dot-hatched portion in FIG. 9) depending on processing conditions.

The plasma that has spread to downstream, which is not necessary for the processing of the substrate 7 at all, would incur deterioration of the processing efficiency to the power inputted to the vacuum chamber 1 as a processing chamber. Further, the contamination of the vacuum chamber 1 due to the processing would also spread to downstream, leading to increases in the maintenance work.

### SUMMARY OF THE INVENTION

In view of these and other prior-art issues, the present invention is purposed to provide a plasma processing method and apparatus which is less liable to occurrence of plasma spread to the region downstream of the substrate electrode, good at power efficiency, and capable of reducing the maintenance work.

In accomplishing these and other aspects, according to a first aspect of the present invention, there is provided a plasma processing method for generating plasma within a grounded vacuum chamber and processing a substrate placed on a substrate electrode within the vacuum chamber, the plasma being generated by applying a high-frequency power having a frequency of 100 kHz to 3 GHz to an antenna provided opposite to the substrate while interior of the vacuum chamber is controlled to a pressure by supplying a gas into the vacuum chamber and simultaneously exhausting the interior of the vacuum chamber, the method comprising:

in a state that the vacuum chamber is separated into a region on one side on which the substrate is present and a region on the other side on which the substrate is absent by a plurality of layers of porous conductor which are grounded at nearly all of their outer peripheral portions, processing the substrate under a condition that plasma has not reached the region on the side on which the substrate is absent.

According to a second aspect of the present invention, there is provided a plasma processing method for generating plasma within a grounded vacuum chamber and processing a substrate placed on a substrate electrode within the vacuum chamber, the plasma being generated by applying a high-frequency power having a frequency of 100 kHz to 3 GHz to an antenna provided opposite to the substrate while interior of the vacuum chamber is controlled to a pressure by supplying a gas into the vacuum chamber and simultaneously exhausting the interior of the vacuum chamber, the method comprising:

in a state that the vacuum chamber is separated into a region on one side on which the substrate is present and a region on the other side on which the substrate is absent by a porous conductor which is grounded at nearly all of its outer peripheral portion as well as a porous wave absorber for absorbing waves, processing the substrate under a condition that plasma has not reached the region on the side on which the substrate is absent.

According to a third aspect of the present invention, there is provided a plasma processing apparatus comprising:

a gas supply unit for supplying gas into a grounded vacuum chamber;

an exhausting unit for exhausting interior of the vacuum chamber;

a pressure-regulating valve for controlling the interior of the vacuum chamber to a pressure;

a substrate electrode on which a substrate is placed within the vacuum chamber;

an antenna provided opposite to the substrate electrode;

high-frequency power supply capable of supplying a high-frequency power having a frequency of 100 kHz to 3 GHz to the antenna; and

a plurality of layers of porous conductor which are grounded at nearly all of their outer peripheral portions and arranged so that the vacuum chamber is separated into a region on one side on which the substrate is present and a region on the other side on which the substrate is absent by the plurality of layers of porous conductor.

According to a fourth aspect of the present invention, there is provided a plasma processing apparatus according to the 3rd aspect, further comprising a turbo-molecular pump for exhausting the vacuum chamber which is disposed just under the substrate electrode, an exhaust port of the vacuum chamber connected to the turbo-molecular pump being placed in the region on the substrate-absent side of the vacuum chamber separated into the two regions.

According to a fifth aspect of the present invention, there is provided a plasma processing apparatus according to the 4th aspect, wherein the pressure-regulating valve for controlling the vacuum chamber to the pressure is an up-and-down valve placed directly under the substrate electrode and just over the turbo-molecular pump, the pressure-regulating valve being placed in the region on the substrate-absent side of the vacuum chamber separated into the two regions.

According to a sixth aspect of the present invention, there is provided a plasma processing apparatus according to the 3rd aspect, wherein frequency of the high-frequency power applied to the antenna is within a range of 50 MHz to 3 GHz.

According to a seventh aspect of the present invention, there is provided a plasma processing apparatus according to the 3rd aspect, wherein an inner wall surface of the vacuum chamber is covered with an inner chamber-forming member, and one side of the inner chamber-forming member downstream of its opening portion is grounded so that electromagnetic waves do not leak to the region on the substrate-absent side of the vacuum chamber separated into the two regions through a gap between the inner chamber-forming member and the inner wall surface of the vacuum chamber.

According to an eighth aspect of the present invention, there is provided a plasma processing apparatus according to the 3rd aspect, wherein distance between the plurality of layers of porous conductor is within a range of 3 mm to 20 mm.

According to a ninth aspect of the present invention, there is provided a plasma processing apparatus according to the 3rd aspect, wherein porosity per unit area of the plurality of layers of porous conductor is not less than 50% each.

According to a 10th aspect of the present invention, there is provided a plasma processing apparatus comprising:

a gas supply unit for supplying gas into a grounded vacuum chamber;

an exhausting unit for exhausting interior of the vacuum chamber;

a pressure-regulating valve for controlling the interior of the vacuum chamber to a pressure;

a substrate electrode on which a substrate is placed within the vacuum chamber;

an antenna provided opposite to the substrate electrode;

high-frequency power supply capable of supplying a high-frequency power having a frequency of 100 kHz to 3 GHz to the antenna; and

a porous conductor which is grounded at nearly all of its outer peripheral portion, and a porous wave absorber by both of which the vacuum chamber is separated into a region on one side on which the substrate is present and a region on the other side on which the substrate is absent.

According to an 11th aspect of the present invention, there is provided a plasma processing apparatus according to the 10th aspect, wherein the porous conductor faces the region on the substrate-present side of the vacuum chamber separated into the two regions while the porous wave absorber faces the region on the substrate-absent side of the vacuum chamber separated into the two regions.

According to a 12th aspect of the present invention, there is provided a plasma processing apparatus according to the 10th aspect, further comprising a turbo-molecular pump for exhausting the vacuum chamber which is disposed just under the substrate electrode, an exhaust port of the chamber connected to the turbo-molecular pump being placed in the region on the substrate-absent side of the vacuum chamber separated into the two regions.

According to a 13th aspect of the present invention, there is provided a plasma processing apparatus according to the 12th aspect, wherein the pressure-regulating valve for controlling the vacuum chamber to the pressure is an up-and-down valve placed directly under the substrate electrode and just over the turbo-molecular pump, the pressure-regulating valve being placed in the region on the substrate-absent side of the vacuum chamber separated into the two regions.

According to a 14th aspect of the present invention, there is provided a plasma processing apparatus according to the 10th aspect, wherein frequency of the high-frequency power applied to the antenna is within a range of 50 MHz to 3 GHz.

According to a 15th aspect of the present invention, there is provided a plasma processing apparatus according to the 10th aspect, wherein an inner wall surface of the vacuum chamber is covered with an inner chamber-forming member, and one side of the inner chamber-forming member downstream of its opening portion is grounded so that electromagnetic waves do not leak to the region on the substrate-absent side of the vacuum chamber separated into the two regions through a gap between the inner chamber-forming member and the inner wall surface of the vacuum chamber.

According to a 16th aspect of the present invention, there is provided a plasma processing apparatus according to the 10th aspect, wherein distance between the porous conductor and the porous wave absorber is within a range of 3 mm to 20 mm.

According to a 17th aspect of the present invention, there is provided a plasma processing apparatus according to the 10th aspect, wherein porosities per unit area of the porous conductor and the porous wave absorber are not less than 50% each.

According to an 18th aspect of the present invention, there is provided a plasma processing method for generating plasma within a grounded vacuum chamber and processing a substrate placed on a substrate electrode within the vacuum chamber, the plasma being generated by applying a high-frequency power having a frequency of 100 kHz to 3 GHz to an antenna provided opposite to the substrate while interior of the vacuum chamber is controlled to a pressure by supplying a gas into the vacuum chamber and simultaneously exhausting the interior of the vacuum chamber, the method comprising:

in a state that the vacuum chamber is separated into a region on one side on which the substrate is present and a region on the other side on which the substrate is absent by a porous conductor which is grounded, processing the substrate under a condition that plasma has not reached the region on the side on which the substrate is absent.

According to a 19th aspect of the present invention, there is provided a plasma processing method for generating plasma within a grounded vacuum chamber and processing a substrate placed on a substrate electrode within the vacuum chamber, the plasma being generated by applying a high-frequency power having a frequency of 100 kHz to 3 GHz to an antenna provided opposite to the substrate while interior of the vacuum chamber is controlled to a pressure by supplying a gas into the vacuum chamber and simultaneously exhausting the interior of the vacuum chamber, the method comprising:

in a state that the vacuum chamber is separated into a region on one side on which the substrate is present and a region on the other side on which the substrate is absent by a porous wave absorber for absorbing waves, processing the substrate under a condition that plasma has not reached the region on the side on which the substrate is absent.

According to a 20th aspect of the present invention, there is provided a plasma processing method according to claim 18, wherein the substrate is processed under a condition that an inner wall surface of the vacuum chamber is covered with an inner chamber-forming member, and one side of the inner chamber-forming member downstream of its opening portion is grounded so that electromagnetic waves do not leak to the region on the substrate-absent side of the vacuum chamber separated into the two regions through the opening portion of the inner chamber-forming member.

According to a 21st aspect of the present invention, there is provided a plasma processing apparatus comprising:

a gas supply unit for supplying gas into a grounded vacuum chamber;

an exhausting unit for exhausting interior of the vacuum chamber;

a pressure-regulating valve for controlling the interior of the vacuum chamber to a pressure;

a substrate electrode on which a substrate is placed within the vacuum chamber;

an antenna provided opposite to the substrate electrode;

high-frequency power supply capable of supplying a high-frequency power having a frequency of 100 kHz to 3 GHz to the antenna; and

a porous conductor which is grounded and arranged so that the vacuum chamber is separated into a region on one side on which the substrate is present and a region on the other side on which the substrate is absent by the porous conductor.

According to a 22nd aspect of the present invention, there is provided a plasma processing apparatus comprising:

a gas supply unit for supplying gas into a grounded vacuum chamber;

an exhausting unit for exhausting interior of the vacuum chamber;

a pressure-regulating valve for controlling the interior of the vacuum chamber to a pressure;

a substrate electrode on which a substrate is placed within the vacuum chamber;

an antenna provided opposite to the substrate electrode;

high-frequency power supply capable of supplying a high-frequency power having a frequency of 100 kHz to 3 GHz to the antenna; and

a porous wave absorber which is grounded and arranged so that the vacuum chamber is separated into a region on one side on which the substrate is present and a region on the other side on which the substrate is absent by the porous wave absorber.

According to a 23rd aspect of the present invention, there is provided a plasma processing apparatus according to the 21st aspect, wherein when a hole pitch of the porous conductor is p, a frequency of the high-frequency power to be applied to the antenna is f, and a light velocity is c, a relational expression of

p<0.002×c/f

is satisfied.

According to a 24th aspect of the present invention, there is provided a plasma processing apparatus according to the 21st aspect, wherein when a hole pitch of the porous conductor is p, a frequency of the high-frequency power to be applied to the antenna is f, and a light velocity is c, a relational expression of

p<0.0005×c/f

is satisfied.

According to a 25th aspect of the present invention, there is provided a plasma processing apparatus according to the 22nd aspect, wherein when a hole pitch of the wave absorber is p, a frequency of the high-frequency power to be applied to the antenna is f, and a light velocity is c, a relational expression of

p<0.02×c/f

is satisfied.

According to a 26th aspect of the present invention, there is provided a plasma processing apparatus according to the 22nd aspect, wherein when a hole pitch of the wave absorber is p, a frequency of the high-frequency power to be applied to the antenna is f, and a light velocity is c, a relational expression of

p<0.005×c/f

is satisfied.

According to a 27th aspect of the present invention, there is provided a plasma processing method for generating plasma within a grounded vacuum chamber and processing a substrate placed on a substrate electrode within the vacuum chamber, the plasma being generated by applying a high-frequency power having a frequency of 100 kHz to 3 GHz to an antenna provided opposite to the substrate while interior of the vacuum chamber is controlled to a pressure by supplying a gas into the vacuum chamber and simultaneously exhausting the interior of the vacuum chamber, the method comprising:

in a state that the vacuum chamber is separated into a region on one side on which the substrate is present and a region on the other side on which the substrate is absent by a shielding plate which is grounded and comprised of a multiplicity of conductor thin plates radially extending from the substrate electrode toward an inner wall surface of the vacuum chamber, processing the substrate under a condition that plasma has not reached the region on the side on which the substrate is absent.

According to a 28th aspect of the present invention, there is provided a plasma processing method for generating plasma within a grounded vacuum chamber and processing a substrate placed on a substrate electrode within the vacuum chamber, the plasma being generated by applying a high-frequency power having a frequency of 100 kHz to 3 GHz to an antenna provided opposite to the substrate while interior of the vacuum chamber is controlled to a pressure by supplying a gas into the vacuum chamber and simultaneously exhausting the interior of the vacuum chamber, the method comprising:

in a state that the vacuum chamber is separated into a region on one side on which the substrate is present and a region on the other side on which the substrate is absent by a shielding plate which is grounded and comprised of a multiplicity of conductor bars radially extending from the substrate electrode toward an inner wall surface of the vacuum chamber, processing the substrate under a condition that plasma has not reached the region on the side on which the substrate is absent.

According to a 29th aspect of the present invention, there is provided a plasma processing apparatus comprising:

a gas supply unit for supplying gas into a grounded vacuum chamber;

an exhausting unit for exhausting interior of the vacuum chamber;

a pressure-regulating valve for controlling the interior of the vacuum chamber to a pressure;

a substrate electrode on which a substrate is placed within the vacuum chamber;

an antenna provided opposite to the substrate electrode;

high-frequency power supply capable of supplying a high-frequency power having a frequency of 100 kHz to 3 GHz to the antenna; and

a shielding plate which is grounded and comprised of a multiplicity of conductor thin plates radially extending from the substrate electrode toward an inner wall surface of the vacuum chamber and arranged so that the vacuum chamber is separated into a region on one side on which the substrate is present and a region on the other side on which the substrate is absent by the shielding plate.

According to a 30th aspect of the present invention, there is provided a plasma processing apparatus comprising:

a gas supply unit for supplying gas into a grounded vacuum chamber;

an exhausting unit for exhausting interior of the vacuum chamber;

a pressure-regulating valve for controlling the interior of the vacuum chamber to a pressure;

a substrate electrode on which a substrate is placed within the vacuum chamber;

an antenna provided opposite to the substrate electrode;

high-frequency power supply capable of supplying a high-frequency power having a frequency of 100 kHz to 3 GHz to the antenna; and

a shielding plate which is grounded and comprised of a multiplicity of conductor bars radially extending from the substrate electrode toward an inner wall surface of the vacuum chamber and arranged so that the vacuum chamber is separated into a region on one side on which the substrate is present and a region on the other side on which the substrate is absent by the shielding plate.

According to a 31st aspect of the present invention, there is provided a plasma processing apparatus according to the 29th aspect, wherein when a width of void between the multiplicity of conductor thin plates is p, a frequency of the high-frequency power to be applied to the antenna is f, and a light velocity is c, a relational expression of

p<0.003×c/f

is satisfied.

According to a 32nd aspect of the present invention, there is provided a plasma processing apparatus according to the 29th aspect, wherein when a width of void between the multiplicity of conductor thin plates is p, a frequency of the high-frequency power to be applied to the antenna is f, and a light velocity is c, a relational expression of

p<0.001×c/f

is satisfied.

According to a 33rd aspect of the present invention, there is provided a plasma processing apparatus according to the 30th aspect, wherein when a width of void between the multiplicity of conductor bars is p, a frequency of the high-frequency power to be applied to the antenna is f, and a light velocity is c, a relational expression of

p<0.01×c/f

is satisfied.

According to a 34th aspect of the present invention, there is provided a plasma processing apparatus according to the 30th aspect, wherein when a width of void between the multiplicity of conductor bars is p, a frequency of the high-frequency power to be applied to the antenna is f, and a light velocity is c, a relational expression of

p<0.003×c/f

is satisfied.

### BRIEF DESCRIPTION OF THE DRAWINGS

These and other aspects and features of the present invention will become clear from the following description taken in conjunction with the preferred embodiments thereof with reference to the accompanying drawings, in which:

FIG. 1 is a sectional view showing the construction of a plasma processing apparatus used in a first embodiment of the present invention;

FIG. 2 is a plan view showing the construction of the plasma processing apparatus used in the first embodiment of the present invention;

FIG. 3 is a plan view of an antenna used in the first embodiment of the present invention;

FIG. 4 is a sectional view showing the construction of a plasma processing apparatus used in a second embodiment of the present invention;

FIG. 5 is a plan view showing the construction of the plasma processing apparatus used in the second embodiment of the present invention;

FIG. 6 is a sectional view showing the construction in which the present invention is applied to a plasma processing apparatus of the inductively-coupling plasma source system;

FIG. 7 is a sectional view showing the construction in which the present invention is applied to a plasma processing apparatus of the surface-wave plasma source system;

FIG. 8 is a sectional view showing the construction of a plasma processing apparatus which is a modification of the first embodiment of the present invention;

FIG. 9 is a sectional view showing the construction of a plasma processing apparatus used in a prior-art example;

FIG. 10 is a graph showing a relationship between luminous intensity on downstream side and pitch (c/f) at power of 500 W;

FIG. 11 is a graph showing a relationship between luminous intensity on downstream side and pitch (c/f) at power of 1500 W;

FIG. 12 is an enlarged sectional view of the grounding point of the plasma processing apparatus of the first embodiment;

FIG. 13 is a sectional view showing the construction of a plasma processing apparatus used in a third embodiment of the present invention;

FIG. 14 is a plan view showing the construction of the plasma processing apparatus used in the third embodiment of the present invention;

FIG. 15 is a plan view of an antenna used in the third embodiment of the present invention;

FIG. 16 is a sectional view showing the construction of a plasma processing apparatus used in a fourth embodiment of the present invention;

FIG. 17 is a plan view showing the construction of the plasma processing apparatus used in the fourth embodiment of the present invention;

FIG. 18 is a sectional view showing the construction in which the present invention is applied to a plasma processing apparatus of the inductively-coupling plasma source system;

FIG. 19 is a sectional view showing the construction in which the present invention is applied to a plasma processing apparatus of the surface-wave plasma source system;

FIG. 20 is a sectional view showing the construction of a plasma processing apparatus which is a modification of the present invention; and

FIG. 21 is a sectional view showing an example of the structure of a plasma processing apparatus in which two shielding plates are provided.

### DETAILED DESCRIPTION OF THE PREFERRED EMBODIMENTS

Before the description of the present invention proceeds, it is to be noted that like parts are designated by like reference numerals throughout the accompanying drawings.

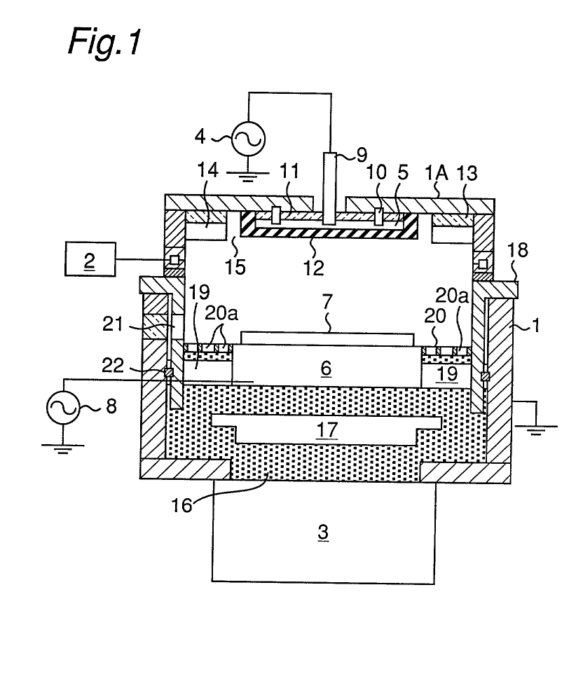

Hereinbelow, a first embodiment of the present invention is described with reference to FIGS. 1 to 3.

FIG. 1 shows a sectional view of a plasma processing apparatus used in the first embodiment of the present invention. Referring to FIG. 1, while interior of a vacuum chamber 1 which can be defined in, for example, a vacuum vessel is maintained to a specified pressure by introducing a specified gas from a gas supply unit 2 into the vacuum chamber 1 and simultaneously performing exhaustion by a turbo-molecular pump 3 as an exhauster, a high-frequency power of 100 MHz is supplied by an antenna use high-frequency power supply 4 to an antenna 5 provided so as to project into the vacuum chamber 1. Then, plasma is generated in the vacuum chamber 1, allowing plasma processing to be carried out with a substrate 7 placed on a substrate electrode 6. There is also provided a substrate-electrode use high-frequency power supply 8 for supplying high-frequency power to the substrate electrode 6, making it possible to control ion energy that reaches the substrate 7. The high-frequency voltage supplied to the antenna 5 is delivered to a proximity to the center of the antenna 5 by a feed bar 9. A plurality of sites of the antenna 5 other than its center and peripheries, and a face 1A of the vacuum chamber 1 opposite to the substrate 7 are short-circuited by short pins 10. A dielectric plate 11 is sandwiched between the antenna 5 and the vacuum chamber 1, and the feed bar 9 and the short pins 10 serve to connect the antenna 5 and the antenna use high-frequency power supply 4 to each other, and the antenna 5 and the vacuum chamber 1 to each other, respectively, via through holes provided in the dielectric plate 11. Also, surfaces of the antenna 5 are covered with an insulating cover 12. Further, a plasma trap 15 is provided so as to comprise a groove-shaped space between the dielectric plate 11 and a dielectric ring 13 provided at a peripheral portion of the dielectric plate 11, and a groove-shaped space between the antenna 5 and a conductor ring 14 provided at a peripheral portion of the antenna 5.

The turbo-molecular pump 3 and an exhaust port 16 connected to the pump 3 of the vacuum chamber 1 are disposed just under the substrate electrode 6, and a pressure-regulating valve 17 for controlling the vacuum chamber 1 to a specified pressure is an up-and-down valve disposed directly under the substrate electrode 6 and just over the turbo-molecular pump 3. Also, a conductive inner chamber-forming member 18 covers the inner wall surface of the vacuum chamber 1, thereby preventing the vacuum chamber 1 from being contaminated by plasma processing. After a specified number of substrates 7 have been processed, the contaminated inner chamber-forming member 18 is replaced with a rotation component, thus considerations being given so that the maintenance work can promptly be carried out. The substrate electrode 6 is fixed to the vacuum chamber 1 with four pillars 19 arranged at equal intervals.

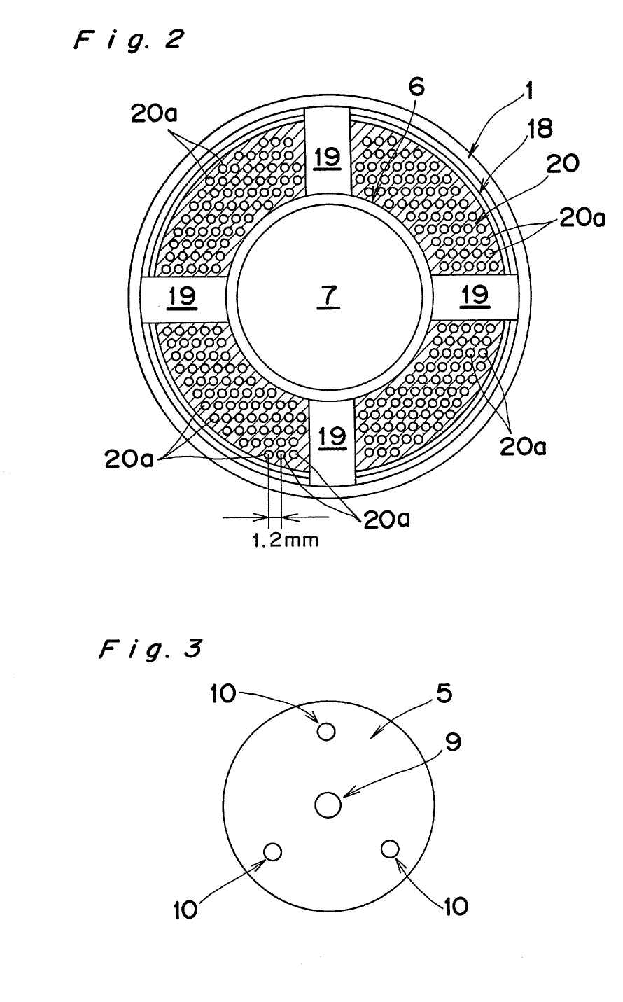

The vacuum chamber 1 is grounded, and separated into a region on one side on which the substrate 7 is present and a region on the other side on which the substrate 7 is absent (hatched portion in FIG. 1) by a conductive punching metal plate 20 (serving as one example of a porous conductor) nearly all the peripheral portion of which is grounded. The punching metal plate 20 has many holes 20a arranged approximately uniformly and is made of aluminum etc. The punching metal plate 20 has a porosity per unit area of 30-90%. If the porosity per unit area is less than 30%, the exhaustion rate is remarkably decreased, while the porosity per unit area is over 90%, it is difficult to manufacture the plate 20. As shown in FIG. 2, which is a plan view of the plasma processing apparatus, the punching-hole pitch of the punching metal plate 20 is 1.2 mm. Whereas FIG. 2 depicts the punching holes 20a rather larger for simplicity's sake, the number of punching holes 20a is actually much greater. Typically, the diameter of the substrate electrode 6 is 220 mm, the inner diameter of the inner chamber-forming member 18 is 450 mm, and the punching holes 20a are provided radially, counting a number of (450−220)/(2×1.2)≈95. Further, a grounding is provided at a grounding point 22 (FIG. 1) in the downstream of an opening 21 of the inner chamber-forming member 18 (the opening 21 being a gate for putting a wafer into and out of the vacuum chamber 1, a viewing port for observing plasma emission etc.) so that electromagnetic waves do not leak through the opening 21 to the region on the side of the vacuum chamber 1 on which the substrate 7 is absent, the vacuum chamber 1 being separated into the two regions. One example of the grounding point 22 may be a metal ring brought into contact with the inner chamber-forming member 18 and the vacuum chamber 1. See FIG. 12. FIG. 12 is an enlarged sectional view of the grounding point of the plasma processing apparatus of the first embodiment. The grounding point 12 is constructed by an annular metal ring which brought into contact with the inner chamber-forming member 18 with a plurality of conductive spiral tubes 55 and brought into contact with the vacuum chamber 1 with a plurality of conductive spiral tubes 55.

FIG. 3 shows a plan view of the antenna 5. In FIG. 3, the short pins 10 are provided at three sites so as to be equidistantly placed to the center of the antenna 5.

In the plasma processing apparatus shown in FIGS. 1 to 3, a substrate with an iridium film was etched. Etching conditions were a ratio of argon/chlorine=260/20 sccm, a pressure of 0.3 Pa, an antenna power of 1500 W, and a substrate electrode power of 400 W. As a result of performing etching process under these conditions, there occurred no plasma spread to the region downstream of the substrate electrode 6 (dot-hatched portion of FIG. 1), so that a successful discharge state was able to be obtained.

The reason that discharge in the downstream was able to be suppressed as shown above could be that high-frequency electromagnetic waves were shielded by the punching metal plate 20, inhibiting the electromagnetic waves from reaching the downstream. Since plasma does not spread to the downstream, processing efficiency to the power inputted to the vacuum chamber 1 serving as a processing chamber is improved over the prior-art example, resulting in a 9% improvement of etching rate under the same etching conditions (prior-art example: 79 nm/min., first embodiment of the present invention: 86 nm/min.). Neither did contamination of the vacuum chamber 1 due to the processing spread to the downstream, which allowed the burden of the maintenance work to be reduced.

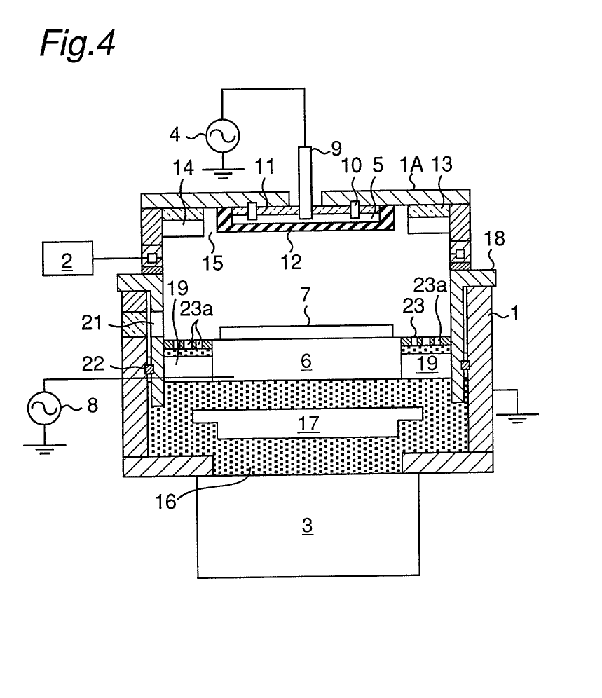

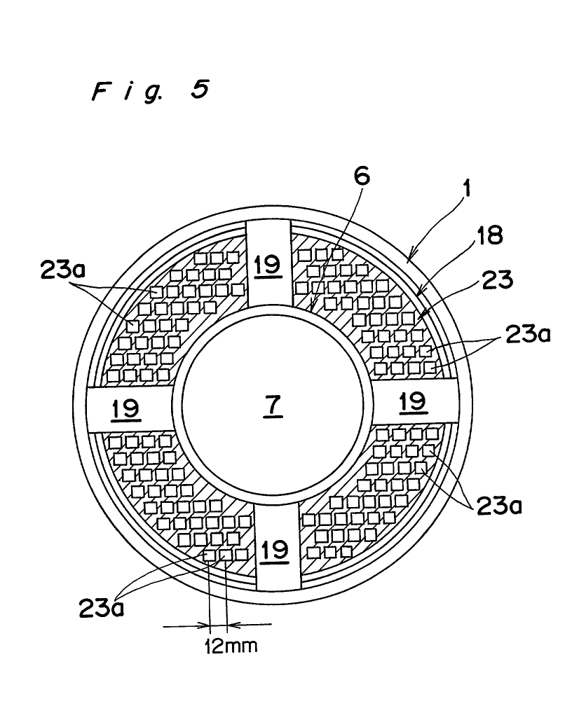

Next, a second embodiment of the present invention is described with reference to FIGS. 4 and 5.

FIG. 4 shows a sectional view of a plasma processing apparatus used in the second embodiment of the present invention. Referring to FIG. 4, while interior of a vacuum chamber 1 is maintained to a specified pressure by introducing a specified gas from a gas supply unit 2 into the vacuum chamber 1 and simultaneously performing exhaustion by a turbo-molecular pump 3 as an exhauster, a high-frequency power of 100 MHz is supplied by an antenna use high-frequency power supply 4 to an antenna 5 provided so as to project into the vacuum chamber 1. Then, plasma is generated in the vacuum chamber 1, allowing plasma processing to be carried out with a substrate 7 placed on a substrate electrode 6. There is also provided a substrate-electrode use high-frequency power supply 8 for supplying high-frequency power to the substrate electrode 6, making it possible to control ion energy that reaches the substrate 7. The high-frequency voltage supplied to the antenna 5 is delivered to a proximity to the center of the antenna 5 by a feed bar 9. A plurality of sites of the antenna 5 other than its center and peripheries, and a face 1A of the vacuum chamber 1 opposite to the substrate 7 are short-circuited by short pins 10. A dielectric plate 11 is sandwiched between the antenna 5 and the vacuum chamber 1, and the feed bar 9 and the short pins 10 serve to connect the antenna 5 and the antenna use high-frequency power supply 4 to each other, and the antenna 5 and the vacuum chamber 1 to each other, respectively, via through holes provided in the dielectric plate 11. Also, surfaces of the antenna 5 are covered with an insulating cover 12. Further, a plasma trap 15 is provided so as to comprise a groove-shaped space between the dielectric plate 11 and a dielectric ring 13 provided at a peripheral portion of the dielectric plate 11, and a groove-shaped space between the antenna 5 and a conductor ring 14 provided at a peripheral portion of the antenna 5.

The turbo-molecular pump 3 and an exhaust port 16 of the vacuum chamber 1 connected to the pump 3 are disposed just under the substrate electrode 6, and a pressure-regulating valve 17 for controlling the vacuum chamber 1 to a specified pressure is an up-and-down valve disposed directly under the substrate electrode 6 and just over the turbo-molecular pump 3. Also, an inner chamber-forming member 18A covers the inner wall surface of the vacuum chamber 1, thereby preventing the vacuum chamber 1 from being contaminated by plasma processing. After a specified number of substrates 7 have been processed, the contaminated inner chamber-forming member 18A is replaced with a rotation component, thus considerations being given so that the maintenance work can promptly be carried out. The substrate electrode 6 is fixed to the vacuum chamber 1 with four pillars 19 at equal intervals.

The vacuum chamber 1 is grounded, and separated into a region on one side on which the substrate 7 is present and a region on the other side on which the substrate 7 is absent (dot-hatched portion in FIG. 4) by a wave absorber 23. The wave absorber 23 may be one using eddy current loss such as ferrite. As shown in FIG. 5, which is a plan view of the plasma processing apparatus, the pitch of holes 23a provided in the wave absorber 23 is 12 mm. Whereas FIG. 5 depicts the holes 23a rather larger for simplicity's sake, the number of holes 23a is actually much greater. Typically, the diameter of the substrate electrode 6 is 220 mm, the inner diameter of the inner chamber-forming member 18A is 450 mm, and the holes 23a in the wave absorber 23 are provided radially, counting a number of (450−220)/(2×12)≈9. Further, a grounding is provided at a grounding point 22 (FIG. 4) in the downstream of an opening 21 of the inner chamber-forming member 18A (the opening 21 being a gate for putting a wafer into and out of the vacuum chamber 1, a viewing port for observing plasma emission etc.) so that electromagnetic waves do not leak through the opening 21 to the region on the side of the vacuum chamber 1 on which the substrate 7 is absent, the vacuum chamber 1 being separated into two regions. One example of the grounding point 22 may be a metal ring brought into contact with the inner chamber-forming member 18 and the vacuum chamber 1.

The plan view of the antenna 5 is similar to FIG. 3 and its description is omitted here.

In the plasma processing apparatus shown in FIGS. 4 to 5, a substrate with a platinum film was etched. Etching conditions were a ratio of argon/chlorine=260/20 sccm, a pressure of 0.3 Pa, an antenna power of 1500 W, and a substrate electrode power of 400 W. As a result of performing etching process under these conditions, there occurred no plasma spread to the region downstream of the substrate electrode 6 (dot-hatched portion of FIG. 1), so that a successful discharge state was able to be obtained.

The reason that discharge in the downstream was able to be suppressed as shown above could be that high-frequency electromagnetic waves were shielded by the wave absorber 23, inhibiting the electromagnetic waves from reaching the downstream. Whereas the punching metal plate 20 was used to reflect the high-frequency electromagnetic waves in the first embodiment, the second embodiment of the present invention differs therefrom in that the wave absorber 23 is used to absorb and damp electromagnetic waves. In the second embodiment of the present invention, there is no need for grounding the outer peripheral portion of the wave absorber 23, offering an advantage that the degree of freedom for design increases. On the other hand, the first embodiment of the present invention is superior in terms of power efficiency since electromagnetic waves are absorbed and damped.

In the second embodiment of the present invention, since plasma does not spread to downstream, processing efficiency to the power inputted to the vacuum chamber 1 serving as a processing chamber is improved over the prior-art example, resulting in a 4% improvement of etching rate under the same etching conditions (prior-art example: 82 nm/min., second embodiment of the present invention: 85 nm/min.). Neither did contamination of the vacuum chamber 1 due to the processing spread to the downstream, which allowed the burden of the maintenance work to be reduced.

The above first and second embodiments of the present invention have exemplified only a part of many variations on configuration of the vacuum chamber, configuration and arrangement of the antenna, and the like out of the application range of the present invention. Needless to say, other many variations may be conceived in applying the present invention, other than the examples given above.

The above first and second embodiments of the present invention have been described on a case where a high-frequency voltage is fed to the antenna via the through holes provided near the center of the dielectric plate, where the antenna and the vacuum chamber are short-circuited with short pins via through holes which are provided at sites other than the center and peripheries of the dielectric plate and which are equidistantly placed to the center of the antenna. With this constitution, the isotropy of plasma can be enhanced. In the case of a small substrate or the like, needless to say, sufficiently high in-plane uniformity can be obtained without using the short pins.

Also, the above first and second embodiments of the present invention have been described on a case where the substrate is processed while plasma distribution on the substrate is controlled by an annular, groove-shaped plasma trap provided between the antenna and the vacuum chamber. With this constitution, plasma uniformity can be enhanced. In the case of a small substrate or the like, needless to say, sufficiently high in-plane uniformity can be obtained without using the plasma trap.

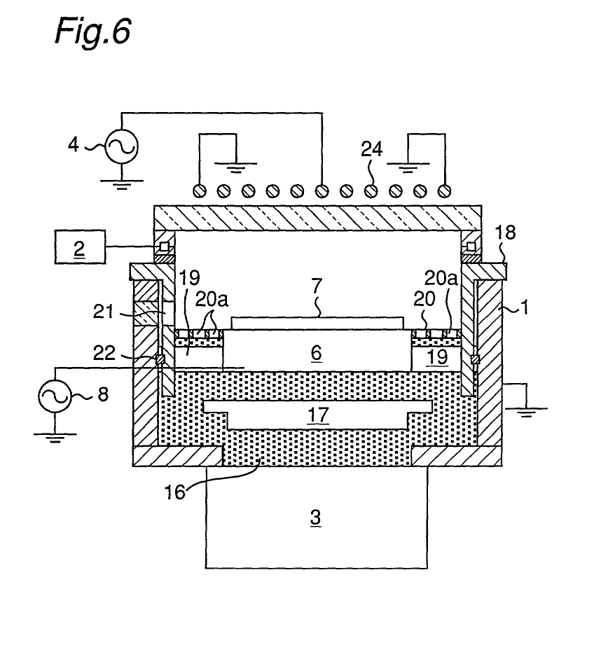

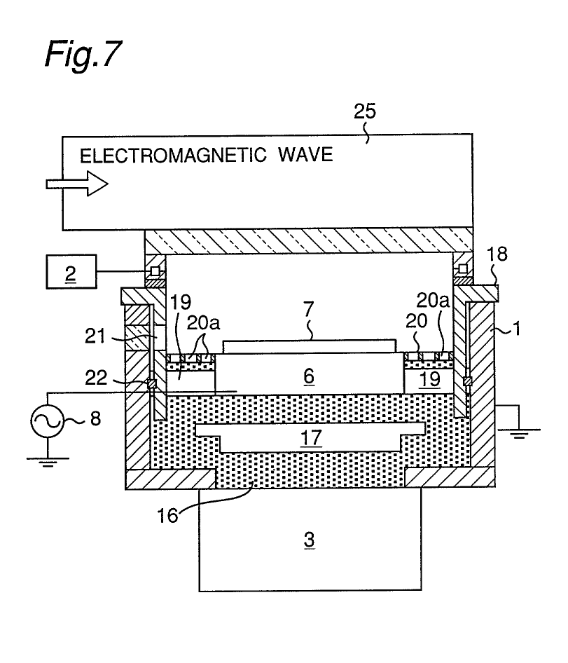

The present invention is also effective for cases where a coil 24 in the inductively coupling plasma source shown in FIG. 6 or an electromagnetic-radiation antenna 25 in the surface-wave plasma source shown in FIG. 7 or the like is used as an antenna.

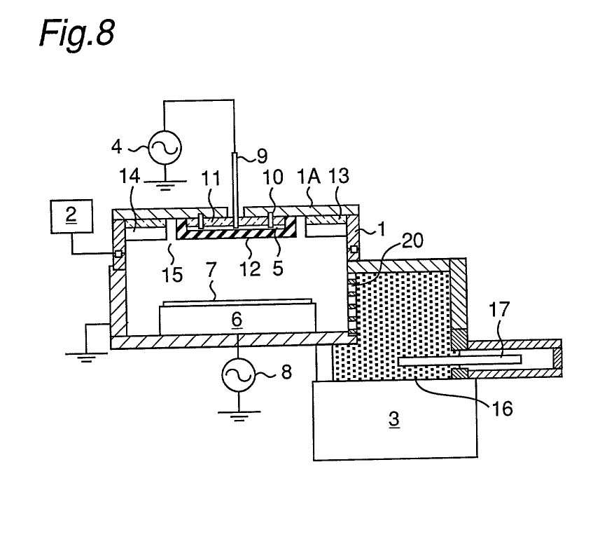

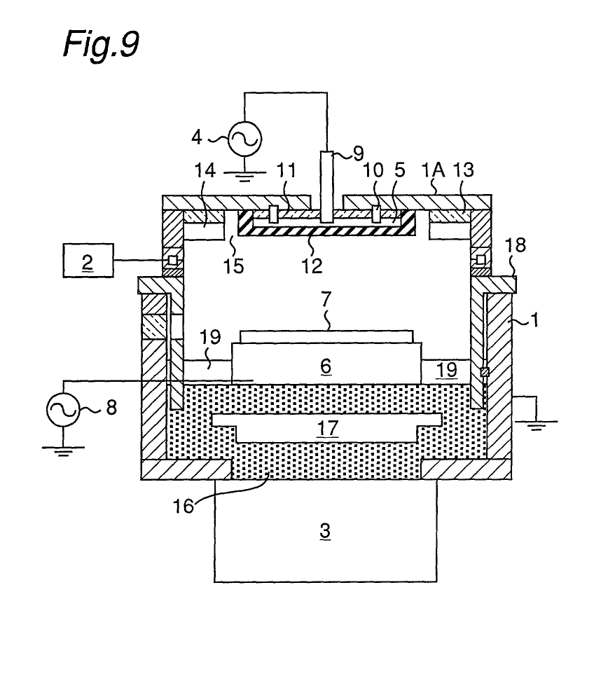

Also, the above first and second embodiments of the present invention have been described on a case where the turbo-molecular pump for exhausting the vacuum chamber is disposed just under the substrate electrode, the vacuum chamber being separated into the two regions, the exhaust port of the vacuum chamber connected to the pump is placed in the one region on one side of the vacuum chamber on which the substrate is absent, and where the pressure-regulating valve for controlling the vacuum chamber to a specified pressure is an up-and-down valve disposed directly under the substrate electrode and just over the turbo-molecular pump, the pressure-regulating valve being placed in the region on the one side of the two-region-separated vacuum chamber on which the substrate is absent. Furthermore, the present invention is effective in the case where, as shown in FIG. 8, the turbo-molecular pump 3 is not placed just under the substrate electrode 6, neither is the pressure-regulating valve 17 placed just under the substrate electrode 6, the pressure-regulating valve 17 being other than an up-and-down valve.

Further, the present invention has been described on a case where the internal pressure of the vacuum chamber is 0.3 Pa as one example. However, since plasma in the downstream becomes more likely to occur the more with the lower internal pressure of the vacuum chamber, the present invention is a method effective for cases where the internal pressure of the vacuum chamber is not higher than 10 Pa. Furthermore, the present invention is a method effective particularly for cases where the internal pressure of the vacuum chamber is not higher than 1 Pa.

Also, the present invention has been described on a case where the frequency of the high-frequency power to be applied on the antenna is 100 MHz as one example. However, for the plasma processing under low pressure, high-frequency power of 100 kHz to 3 GHz can be used, to all the region of which the present invention is effective. Yet, the higher the frequency of the high-frequency power, the wider the range to which the electromagnetic waves tend to spread, making the plasma generation in the downstream more likely to occur. Therefore, the present invention is a method effective for cases where the frequency of the high-frequency power is high, in particular, 50 MHz to 3 GHz.

Also, the first embodiment of the present invention has been described on a case where a punching metal plate is used. Otherwise, using a conductor mesh plate also allows the same effects to be obtained.

Also, the first embodiment of the present invention has been described on a case where the punching-hole pitch of the punching metal plate is 1.2 mm. In this connection, the hole pitch needs to be sufficiently smaller than the wavelength of electromagnetic waves in order to suppress the transmission of electromagnetic waves. For prevention of leakage of electromagnetic waves in the air, a porous conductor such as a conductive punching metal plate or conductor mesh plate in which the hole pitch is smaller than about 0.03 time the wavelength (=c/f) of electromagnetic waves in the vacuum allows enough shielding effects to be obtained. However, considerations must be given to a special phenomenon that the wavelength of electromagnetic waves in the plasma becomes smaller than that in the vacuum. According to our experiments, if the punching-hole pitch of the punching metal plate or mesh pitch of conductor mesh plate is “p,” the frequency of the high-frequency power (for example, 500 W) to be applied to the antenna is “f” and the light velocity is “c,” then satisfying a relational expression of

p<0.002×c/f

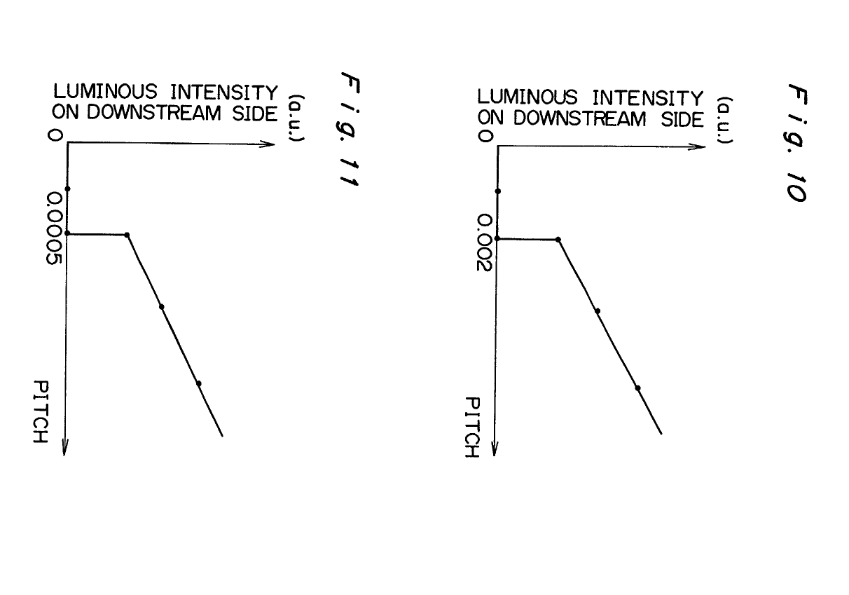

makes it possible to suppress the plasma generation in the downstream over quite a wide range of discharge conditions (See FIG. 10). FIG. 10 is a graph showing a relationship between luminous intensity on downstream side and pitch (c/f) at power of 500 W. That is, if p<0.002×c/f, the luminous intensity on the downstream side can be increased, while if p>0.002×c/f, the luminous intensity on the downstream side is remarkably decreased. For more positive suppression of plasma generation in the downstream, if the punching-hole pitch of the punching metal plate or mesh pitch of conductor mesh plate is “p,” the frequency of the high-frequency power (for example, 1500 W) to be applied to the antenna is “f” and the light velocity is “c,” then it is desirable to satisfy a relational expression of p<0.0005×c/f.

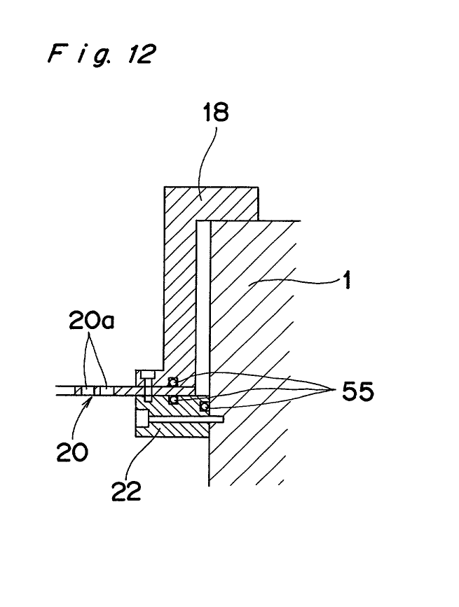

See FIG. 11. FIG. 11 is a graph showing a relationship between luminous intensity on downstream side and pitch (c/f) at power of 1500 W. That is, if p<0.0005×c/f, the luminous intensity on the downstream side can be increased, while if p>0.0005×c/f, the luminous intensity on the downstream side is remarkably decreased.

If the pitch “p” is 1.2 mm, then it is desirable to satisfy a relational expression of p<0.0004×c/f.

Further, the second embodiment of the present invention has been described on a case where the pitch of the holes provided in the wave absorber is 12 mm. However, for the suppression of transmission of electromagnetic waves, the hole pitch needs to be sufficiently smaller than the wavelength of electromagnetic waves. Unlike the case where a porous conductor such as a punching metal plate or conductor mesh plate is used, when a wave absorber is used, electromagnetic waves penetrate inside the wave absorber itself rather than into the holes, damping inside the wave absorber itself. Therefore, the pitch of the holes provided in the wave absorber may be larger than that in the case where the punching metal plate or conductor mesh plate is used. Larger hole pitches produce greater advantages in terms of exhaust characteristics. According to our experiments, if the pitch of the holes provided in the wave absorber is “p,” the frequency of the high-frequency power to be applied to the antenna is “f” and the light velocity is “c,” then it is found that satisfying a relational expression of

p<0.02×c/f

makes it possible to suppress the plasma generation in the downstream over quite a wide range of discharge conditions. For more positive suppression of plasma generation in the downstream, if the pitch of the holes provided in the wave absorber is “p,” the frequency of the high-frequency power to be applied to the antenna is “f” and the light velocity is “c,” then it is desirable to satisfy a relational expression of

p<0.005×c/f.

Further, the above embodiments of the present invention have been described on a case where the inner chamber-forming member covers the inner wall surface of the vacuum chamber and the downstream side of the opening of the inner chamber-forming member is grounded so that electromagnetic waves do not leak through the opening to the region on the side of the vacuum chamber on which the substrate is absent, the vacuum chamber being separated into the two regions. With such a structure, plasma generation in the downstream can be prevented more effectively. In some cases where the high-frequency power is not higher than 500 W, however, plasma generation in the downstream can be prevented without such a structure.

As apparent from the above description, according to the first aspect of the present invention, there is provided a plasma processing method for generating plasma within a vacuum chamber and processing a substrate placed on a substrate electrode within the vacuum chamber, the plasma being generated by applying a high-frequency power having a frequency of 100 kHz to 3 GHz to an antenna provided opposite to the substrate while interior of the vacuum chamber is controlled to a specified pressure by supplying a gas into the vacuum chamber and simultaneously exhausting the interior of the vacuum chamber, wherein the vacuum chamber is grounded, and separated into a region on one side on which the substrate is present and a region on the other side on which the substrate is absent by a porous conductor such as a punching metal plate or conductor mesh plate nearly all the peripheral portion of which is grounded, in which arrangement the substrate is processed in the state that plasma has not sneaked up to the region on the side on which the substrate is absent. Therefore, a plasma processing method which is good at power efficiency and capable of reducing the maintenance work can be realized.

Also, according to the second aspect of the present invention, there is provided a plasma processing method for generating plasma within a vacuum chamber and processing a substrate placed on a substrate electrode within the vacuum chamber, the plasma being generated by applying a high-frequency power having a frequency of 100 kHz to 3 GHz to an antenna provided opposite to the substrate while interior of the vacuum chamber is controlled to a specified pressure by supplying a gas into the vacuum chamber and simultaneously exhausting the interior of the vacuum chamber, wherein the vacuum chamber is grounded, and separated into a region on one side on which the substrate is present and a region on the other side on which the substrate is absent by a wave absorber in which a multiplicity of holes are provided, in which arrangement the substrate is processed in the state that plasma has not sneaked up to the region on the side on which the substrate is absent. Therefore, a plasma processing method which is good at power efficiency and capable of reducing the maintenance work can be realized.

Also, according to the third aspect of the present invention, there is provided a plasma processing apparatus comprising: a vacuum chamber; a gas supply unit for supplying gas into the vacuum chamber; an exhausting unit for exhausting interior of the vacuum chamber; a pressure-regulating valve for controlling the interior of the vacuum chamber to a specified pressure; a substrate electrode on which a substrate is placed within the vacuum chamber; an antenna provided opposite to the substrate electrode; and high-frequency power supply capable of applying a high-frequency power having a frequency of 100 kHz to 3 GHz to the antenna, wherein the vacuum chamber is grounded, and separated into a region on one side on which the substrate is present and a region on the other side on which the substrate is absent by a porous conductor such as a conductive punching metal plate or conductor mesh plate nearly all the peripheral portion of which is grounded. Therefore, a plasma processing apparatus which is less liable to occurrence of plasma spread to the region downstream of the substrate electrode, good at power efficiency, and capable of reducing the maintenance work can be realized.

Also, according to the fourth aspect of the present invention, there is provided a plasma processing apparatus comprising: a vacuum chamber; a gas supply unit for supplying gas into the vacuum chamber; an exhausting unit for exhausting interior of the vacuum chamber; a pressure-regulating valve for controlling the interior of the vacuum chamber to a specified pressure; a substrate electrode on which a substrate is placed within the vacuum chamber; an antenna provided opposite to the substrate electrode; and high-frequency power supply capable of applying a high-frequency power having a frequency of 100 kHz to 3 GHz to the antenna, wherein the vacuum chamber is grounded, and separated into a region on one side on which the substrate is present and a region on the other side on which the substrate is absent by a wave absorber in which a multiplicity of holes are provided. Therefore, a plasma processing apparatus which is less liable to occurrence of plasma spread to the region downstream of the substrate electrode, good at power efficiency, and capable of reducing the maintenance work can be realized.

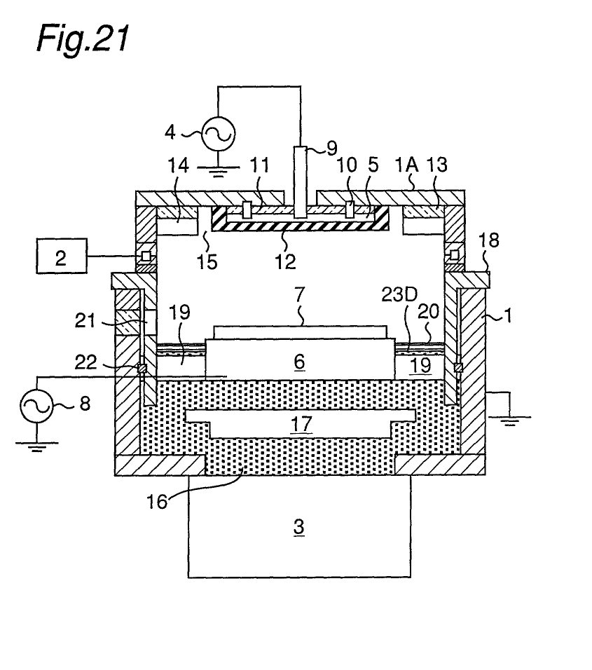

FIG. 21 is a sectional view showing an example of the structure of a plasma processing apparatus in which two porous conductors such as shielding plates or a porous conductor and a porous wave absorber are provided, according to a fifth embodiment of the present invention.

In the fifth embodiment, the two porous conductors are the punching metal plate 20 and the shielding plate 23D as one example. By using the plurality of layers of porous conductor, while sneak of electromagnetic waves can be prevented effectively while decrease in exhaust speed can be minimized.

Advantageous effects in this case can be explained as follows.

The strength of an electric field due to electromagnetic waves leaking to the substrate-absent side of the vacuum chamber separated into two regions is decreased to about 1/10 by one layer of porous conductor having a porosity per unit area of 65%, and the exhaustion rate is decreased to about ⅔ by one layer of porous conductor having a porosity per unit area of 65%. The strength of an electric field due to electromagnetic waves leaking to the substrate-absent side of the vacuum chamber separated into two regions is decreased to about (1/10)²=1/100 by two layers of porous conductor having a porosity per unit area of 65%, and the exhaustion rate is decreased to about (⅔)²=4/9 by one layer of porous conductor having a porosity per unit area of 65%. Meanwhile, in order that the strength of an electric field due to electromagnetic waves leaking to the substrate-absent side of the vacuum chamber separated into two regions is set to 1/100 by one layer of porous conductor, the porosity per unit area of the porous conductor needs to be 20%. In this case, the exhaustion rate is decreased to about ⅕. Accordingly, using two layers of porous conductor having a high porosity per unit area makes it possible to effectively prevent the sneaking of electromagnetic waves while minimizing the decrease in the exhaustion rate.

The wave absorber is formed generally of ferrite, including iron, and so might cause generation of heavy metal pollution on the substrate. Therefore, by providing a structure that the porous conductor faces the region on the substrate-present side of the vacuum chamber separated into the two regions while the porous wave absorber faces the region on the substrate-absent side of the vacuum chamber separated into the two regions, occurrence of pollution can be suppressed. Accordingly, by using the porous conductor and the porous wave absorber, the sneaking of electromagnetic waves can effectively be prevented while the decrease in the exhaustion rate is minimized.

The distance between the plurality of layers of porous conductor is desirably within a range of 3 mm to 30 mm. Less than 3 mm distances tend to increase the sneaking of electromagnetic waves to the substrate-absent side, and conversely, more than 30 mm distances may cause electric discharge to occur in the spaces between the plurality of layers of porous conductor, thus undesirable.

The distance between the porous conductor and the porous wave absorber is desirably within a range of 3 mm to 30 mm. Less than 3 mm distances tend to increase the sneaking of electromagnetic waves to the region on the substrate-absent side, and conversely, more than 30 mm distances may cause electric discharge to occur in the spaces between the layers of the porous conductor and the porous wave absorber, thus undesirable.

The porosity per unit area of the plurality of layers of porous conductor is desirably not less than 50% each. Less than 50% porosities per unit area cause the exhaustion rate to markedly decrease, resulting in less effects of the plurality of layers.

The porosities per unit area of the porous conductor and the porous wave absorber are desirably not less than 50% each. Less than 50% porosities per unit area cause the exhaustion rate to markedly decrease, resulting in less effects of the plurality of layers.

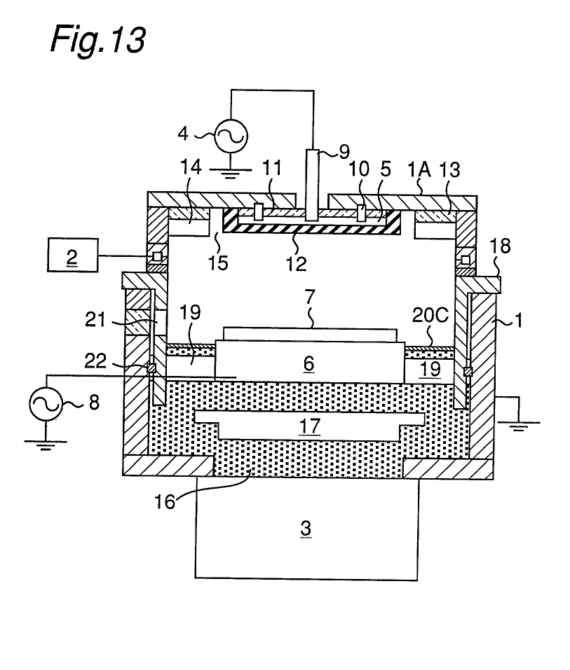

Hereinbelow, a third embodiment of the present invention is described with reference to FIGS. 13 to 15.

FIG. 13 shows a sectional view of a plasma processing apparatus used in the third embodiment of the present invention. Referring to FIG. 13, while interior of a vacuum chamber 1 which can serve as a vacuum chamber is maintained to a specified pressure by introducing a specified gas from a gas supply unit 2 into the vacuum chamber 1 and simultaneously performing exhaustion by a turbo-molecular pump 3 as an exhauster, a high-frequency power of 100 MHz is supplied by an antenna use high-frequency power supply 4 to an antenna 5 provided so as to project into the vacuum chamber 1. Then, plasma is generated in the vacuum chamber 1, allowing plasma processing to be carried out with a substrate 7 placed on a substrate electrode 6. There is also provided a substrate-electrode use high-frequency power supply 8 for supplying high-frequency power to the substrate electrode 6, making it possible to control ion energy that reaches the substrate 7. The high-frequency voltage supplied to the antenna 5 is delivered to a proximity to the center of the antenna 5 by a feed bar 9. A plurality of sites of the antenna 5 other than its center and peripheries, and a face 1A of the vacuum chamber 1 opposite to the substrate 7 are short-circuited by short pins 10. A dielectric plate 11 is sandwiched between the antenna 5 and the vacuum chamber 1, and the feed bar 9 and the short pins 10 serve to connect the antenna 5 and the antenna use high-frequency power supply 4 to each other, and the antenna 5 and the vacuum chamber 1 to each other, respectively, via through holes provided in the dielectric plate 11. Also, surfaces of the antenna 5 are covered with an insulating cover 12. Further, a plasma trap 15 is provided so as to comprise a groove-shaped space between the dielectric plate 11 and a dielectric ring 13 provided at a peripheral portion of the dielectric plate 11, and a groove-shaped space between the antenna 5 and a conductor ring 14 provided at a peripheral portion of the antenna 5.

The turbo-molecular pump 3 and an exhaust port 16 of the vacuum chamber connected to the pump 3 are disposed just under the substrate electrode 6, and a pressure-regulating valve 17 for controlling the vacuum chamber 1 to a specified pressure is an up-and-down valve disposed directly under the substrate electrode 6 and just over the turbo-molecular pump 3. Also, a conductive inner chamber-forming member 18 covers the inner wall surface of the vacuum chamber 1, thereby preventing the vacuum chamber 1 from being contaminated by plasma processing. After a specified number of substrates 7 have been processed, the contaminated inner chamber-forming member 18 is replaced with a rotation component, thus considerations being given so that the maintenance work can promptly be carried out. The substrate electrode 6 is fixed to the vacuum chamber 1 with four pillars 19 arranged at equal intervals.

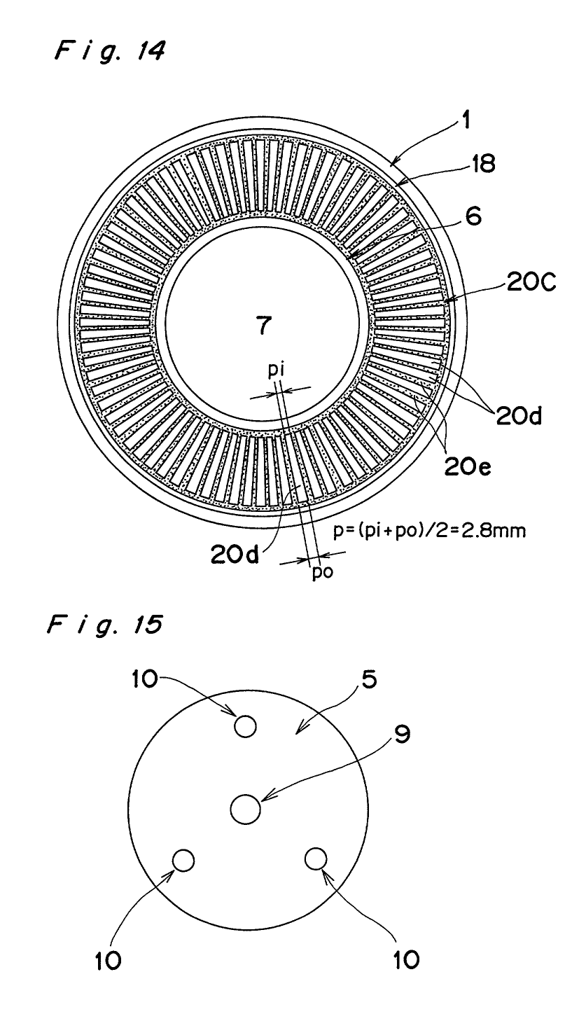

The vacuum chamber 1 is grounded, and separated into a region on one side on which the substrate 7 is present and a region on the other side on which the substrate 7 is absent (dot-hatched portion in FIG. 13) by a shielding plate 20C (serving as one example of a porous conductor) nearly all the peripheral portions of which is grounded and which is comprised of a multiplicity of conductor thin plates 20e radially extending from the substrate electrode 6 toward the inner wall surface of the vacuum chamber 1. As shown in FIG. 14, which is a plan view of the plasma processing apparatus, the width “p” (mean value of inner width “pi” and outer width “po”) of voids 20d between the shielding plate 20C (dot-hatched portions) is 2.8 mm. The width of the conductor thin plates 20e (mean value of inner width and outer width) is 2.2 mm. The shielding plate 20C is formed by performing wet etching process on a 0.5 mm thick aluminum thin plate with etched masks applied, thus the shielding plate 20C being manufacturable with low price and high precision. Utilizing such a manufacturing method involves setting the thickness of the shielding plate 20C to 0.2 to 1 mm. Also, the shielding plate 20C is treated with anodic oxidation (alumite) treatment for prevention of deterioration of the surfaces. It is noted that FIG. 14 depicts the width of the conductor thin plates 20e and the width of voids 20d between the conductor thin plates 20e larger than actual for simplicity' sake, where larger numbers of conductor thin plates 20e and voids 20d therebetween are provided actually. Typically, the diameter of the substrate electrode 6 is 220 mm, the inner diameter of the inner chamber-forming member 18 is 450 mm, and the conductor thin plates 20e and the voids 20d therebetween are provided circumferentially, counting a number of (((450+220)/2)×3.14)/(2.8+2.2)≈210. Further, a grounding is provided at a grounding point 22 (FIG. 13) in the downstream of an opening 21 of the inner chamber-forming member 18 (the opening 21 being a gate for putting a wafer into and out of the vacuum chamber 1, a viewing port for observing plasma emission etc.) so that electromagnetic waves do not leak through the opening 21 to the region on the substrate-absent side (dot-hatched portion in FIG. 13) of the vacuum chamber 1 separated into the two regions via the gap between the inner chamber-forming member 18 and the inner wall surface of the vacuum chamber 1. In addition, needless to say, the structure is designed to exhaust gas from the region on the substrate-present side to the region on the substrate-absent side through the voids 20d between the multiplicity of conductor thin plates 20e. One example of the grounding point 22 may be a metal ring brought into contact with the inner chamber-forming member 18 and the vacuum chamber 1.

FIG. 15 shows a plan view of the antenna 5. In FIG. 15, the short pins 10 are provided at three sites so as to be equidistantly placed to the center of the antenna 5.

In the plasma processing apparatus shown in FIGS. 13 to 15, a substrate with an iridium film was etched. Etching conditions were a ratio of argon/chlorine=260/20 sccm, a pressure of 0.3 Pa, an antenna power of 1500 W, and a substrate electrode power of 400 W. As a result of performing etching process under these conditions, there occurred no plasma spread to the region downstream of the substrate electrode 6 (dot-hatched portion in FIG. 13), so that a successful discharge state was able to be obtained.

The reason that discharge in the downstream was able to be suppressed as shown above could be that high-frequency electromagnetic waves were shielded by the shielding plate 20, inhibiting the electromagnetic waves from reaching the downstream. Although a punching plate or metal mesh plate or the like formed by punching a conductor plate is used for shielding of electromagnetic waves, yet using these as the shielding plate in the plasma processing apparatus would result in a porosity per unit area of about 10 to 40% from the reasons of manufacturing limitations, and this may pose considerable decrease of the exhaustion rate. However, since electromagnetic waves transferring on the inner wall surface of the vacuum chamber have electric field components vertical to the inner wall surface, using the shielding plate 20C (porosity per unit area=2.8/(2.8+2.2)×100=56%) comprised of the multiplicity of conductor thin plates 20e extending radially from the substrate electrode toward the inner wall surface of the vacuum chamber as in the third embodiment also makes it possible to obtain a large shielding effect if the voids 20d between the conductor thin plates 20e are sufficiently small. In addition, in order that decrease in exhaustion rate can be suppressed while the mechanical strength of the shielding plate 20C is maintained, the porosity per unit area of the shielding plate 20C needs to be generally 40% to 70%.

Further, since plasma does not spread to the downstream, processing efficiency to the power inputted to the vacuum chamber 1 serving as a processing chamber is improved over the prior-art example, resulting in an 8% improvement of etching rate under the same etching conditions (prior-art example: 79 nm/min., third embodiment of the present invention: 85 nm/min.). Neither did contamination of the vacuum chamber 1 due to the processing spread to the downstream, which allowed the burden of the maintenance work to be reduced.

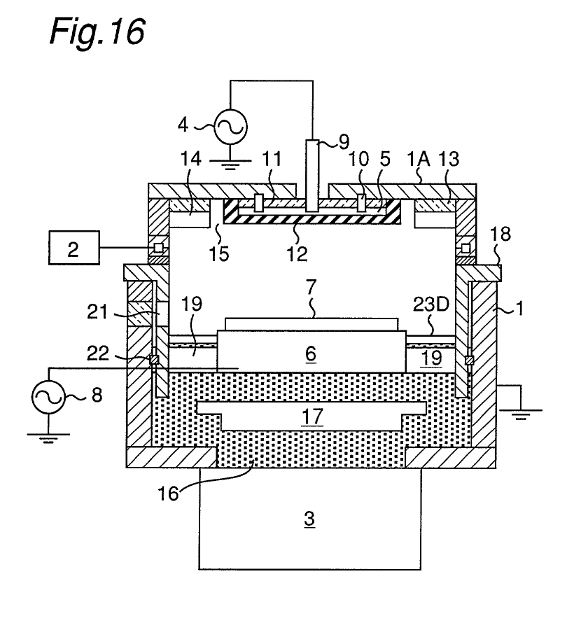

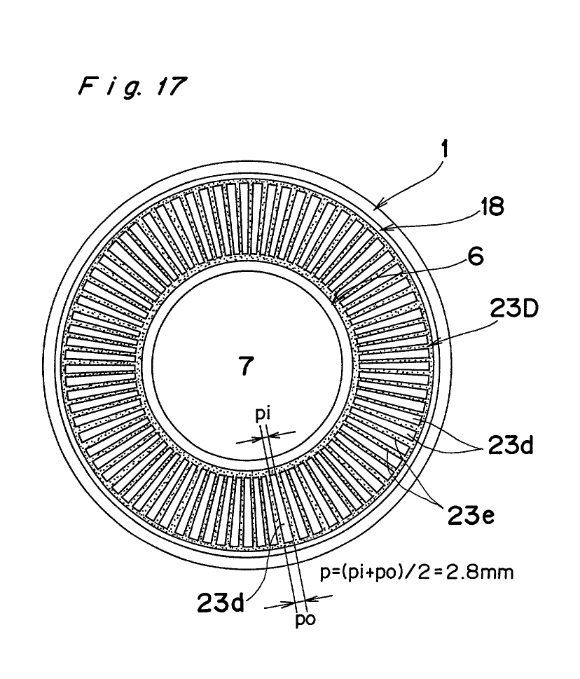

Next, a fourth embodiment of the present invention is described with reference to FIGS. 16 and 17.

FIG. 16 shows a sectional view of a plasma processing apparatus used in the fourth embodiment of the present invention. Referring to FIG. 16, while interior of a vacuum chamber 1 is maintained to a specified pressure by introducing a specified gas from a gas supply unit 2 into the vacuum chamber 1 and simultaneously performing exhaustion by a turbo-molecular pump 3 as an exhauster, a high-frequency power of 100 MHz is supplied by an antenna use high-frequency power supply 4 to an antenna 5 provided so as to project into the vacuum chamber 1. Then, plasma is generated in the vacuum chamber 1, allowing plasma processing to be carried out with a substrate 7 placed on a substrate electrode 6. There is also provided a substrate-electrode use high-frequency power supply 8 for supplying high-frequency power to the substrate electrode 6, making it possible to control ion energy that reaches the substrate 7. The high-frequency voltage supplied to the antenna 5 is delivered to a proximity to the center of the antenna 5 by a feed bar 9. A plurality of sites of the antenna 5 other than its center and peripheries, and a face 1A of the vacuum chamber 1 opposite to the substrate 7 are short-circuited by short pins 10. A dielectric plate 11 is sandwiched between the antenna 5 and the vacuum chamber 1, and the feed bar 9 and the short pins 10 serve to connect the antenna 5 and the antenna use high-frequency power supply 4 to each other, and the antenna 5 and the vacuum chamber 1 to each other, respectively, via through holes provided in the dielectric plate 11. Also, surfaces of the antenna 5 are covered with an insulating cover 12. Further, a plasma trap 15 is provided so as to comprise a groove-shaped space between the dielectric plate 11 and a dielectric ring 13 provided at a peripheral portion of the dielectric plate 11, and a groove-shaped space between the antenna 5 and a conductor ring 14 provided at a peripheral portion of the antenna 5.

The turbo-molecular pump 3 and an exhaust port 16 of the vacuum chamber connected to the pump 3 are disposed just under the substrate electrode 6, and a pressure-regulating valve 17 for controlling the vacuum chamber 1 to a specified pressure is an up-and-down valve disposed directly under the substrate electrode 6 and just over the turbo-molecular pump 3. Also, an inner chamber-forming member 18 covers the inner wall surface of the vacuum chamber 1, thereby preventing the vacuum chamber 1 from being contaminated by plasma processing. After a specified number of substrates 7 have been processed, the contaminated inner chamber-forming member 18 is replaced with a rotation component, thus considerations being given so that the maintenance work can promptly be carried out. The substrate electrode 6 is fixed to the vacuum chamber 1 with four pillars 19 arranged at equal intervals.

The vacuum chamber 1 is grounded, and separated into a region on one side on which the substrate 7 is present and a region on the other side on which the substrate 7 is absent (dot-hatched portion in FIG. 16) by a shielding plate 23D (serving as one example of a porous conductor) which is comprised of a multiplicity of conductor bars 23e radially extending from the substrate electrode 6 toward the inner wall surface of the vacuum chamber 1. As shown in FIG. 17, which is a plan view of the plasma processing apparatus, the width “p” (mean value of inner width “pi” and outer width “po”) of voids 23d between the conductor bars 23e of the shielding plate (dot-hatched portions) 23D is 8 mm. The width of the conductor bars (mean value of inner width and outer width) 23e is 3 mm. The shielding plate 23D is formed by performing machining process on a 9 mm thick aluminum plate, thus the shielding plate 23D being manufacturable with low price and high precision. Utilizing such a manufacturing method involves setting the thickness of the shielding plate 23D to 1 to 30 mm. Also, the shielding plate 23D is treated with anodic oxidation (alumite) treatment for prevention of deterioration of the surfaces. It is noted that FIG. 17 depicts the width of the conductor bars 23e and the width of voids 23d between the conductor bars 23e larger than actual for simplicity' sake, where larger numbers of conductor bars 23e and voids 23d therebetween are provided actually. Typically, the diameter of the substrate electrode 6 is 220 mm, the inner diameter of the inner chamber-forming member 18 is 450 mm, and the conductor bars 23e and the voids 23d therebetween are provided circumferentially, counting a number of (((450+220)/2)×3.14)/(8+3)≈96. Further, a grounding is provided at a grounding point 22 (FIG. 16) in the downstream of an opening 21 of the inner chamber-forming member 18 (the opening 21 being a gate for putting a wafer into and out of the vacuum chamber 1, a viewing port for observing plasma emission etc.) so that electromagnetic waves do not leak through the opening 21 to the region on the substrate-absent side (dot-hatched portion in FIG. 16) of the vacuum chamber 1 separated into the two regions via the gap between the inner chamber-forming member 18 and the inner wall surface of the vacuum chamber 1. In addition, needless to say, the structure is designed to exhaust gas from the region on the substrate-present side to the region on the substrate-absent side through the voids 23d between the multiplicity of conductor bars 23e. One example of the grounding point 22 may be a metal ring brought into contact with the inner chamber-forming member 18 and the vacuum chamber 1.

The plan view of the antenna 5 is similar to FIG. 15.

In the plasma processing apparatus shown in FIGS. 16 to 17, a substrate with an iridium film was etched. Etching conditions were a ratio of argon/chlorine=260/20 sccm, a pressure of 0.3 Pa, an antenna power of 1500 W, and a substrate electrode power of 400 W. As a result of performing etching process under these conditions, there occurred no plasma spread to the region downstream of the substrate electrode 6 (dot-hatched portion in FIG. 16), so that a successful discharge state was able to be obtained.

The reason that discharge in the downstream was able to be suppressed as shown above could be that high-frequency electromagnetic waves were shielded by the shielding plate 23D, inhibiting the electromagnetic waves from reaching the downstream. In the fourth embodiment, a decrease of exhaustion rate due to the larger thickness of the shielding plate 23D as compared with the third embodiment of the present invention is compensated by increasing the porosity per unit area. The possibility that the porosity per unit area can be increased like this is attributable to the fact that the larger the thickness of the shielding plate 23D is, the more the effects of shielding electromagnetic waves are increased. In addition, in order that decrease in exhaustion rate can be suppressed while the mechanical strength of the shielding plate 23D is maintained, the porosity per unit area of the shielding plate 23D needs to be generally 50% to 80%.

Further, in the fourth embodiment, since plasma does not spread to downstream, processing efficiency to the power inputted to the vacuum chamber 1 serving as a processing chamber is improved over the prior-art example, resulting in a 6% improvement of etching rate under the same etching conditions (prior-art example: 79 nm/min., fourth embodiment of the present invention: 84 nm/min.). Neither did contamination of the vacuum chamber 1 due to the processing spread to the downstream, which allowed the burden of the maintenance work to be reduced.

The above third and fourth embodiments of the present invention have exemplified only a part of many variations on configuration of the vacuum chamber, configuration and arrangement of the antenna, and the like out of the application range of the present invention. Needless to say, other many variations may be conceived in applying the present invention, other than the examples given above.

The above third and fourth embodiments of the present invention have been described on a case where a high-frequency voltage is fed to the antenna via the through holes provided near the center of the dielectric plate, where the antenna and the vacuum chamber are short-circuited with short pins via through holes which are provided at sites other than the center and peripheries of the dielectric plate and which are equidistantly placed to the center of the antenna. With this constitution, the isotropy of plasma can be enhanced. In the case of a small substrate or the like, needless to say, sufficiently high in-plane uniformity can be obtained without using the short pins.

Also, the above third and fourth embodiments of the present invention have been described on a case where the substrate is processed while plasma distribution on the substrate is controlled by an annular, groove-shaped plasma trap provided between the antenna and the vacuum chamber. With this constitution, plasma uniformity can be enhanced. In the case of a small substrate or the like, needless to say, sufficiently high in-plane uniformity can be obtained without using the plasma trap.

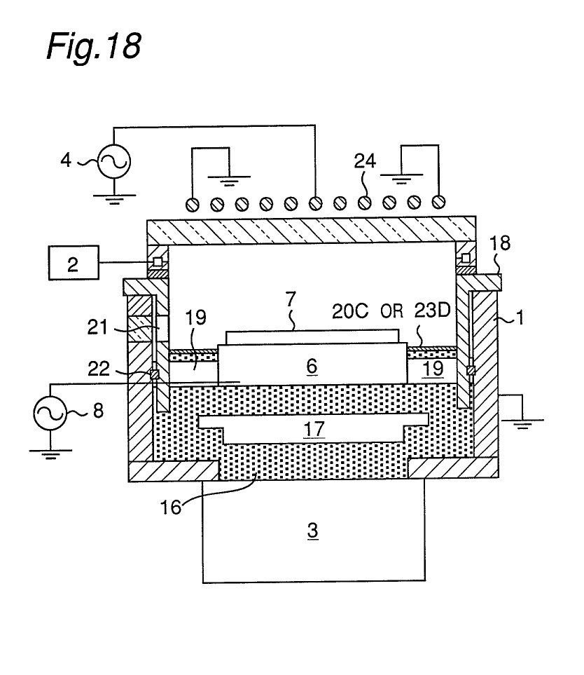

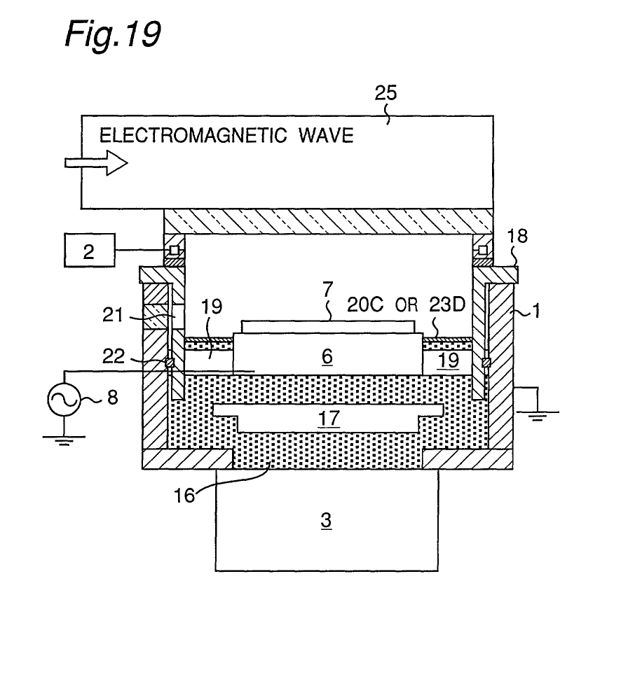

The present invention is also effective for cases where a coil 24 in the inductively coupling plasma source shown in FIG. 18 or an electromagnetic-radiation antenna 25 in the surface-wave plasma source shown in FIG. 19 or the like is used as an antenna.

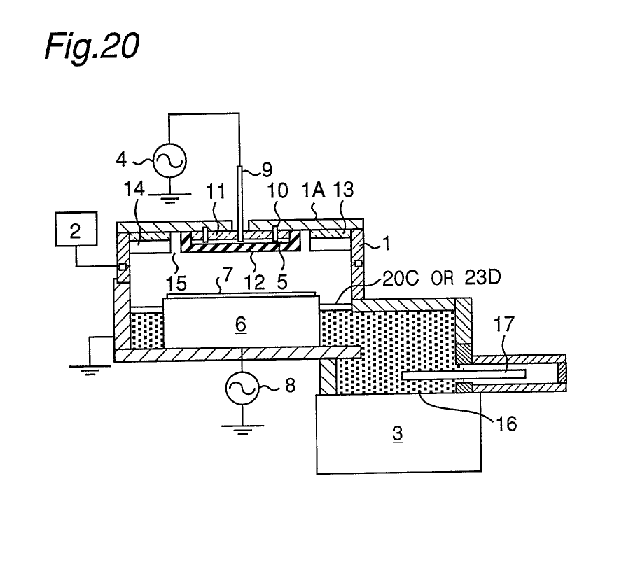

Also, the above third and fourth embodiments of the present invention have been described on a case where the turbo-molecular pump for exhausting the vacuum chamber is disposed just under the substrate electrode, the vacuum chamber being separated into the two regions, the exhaust port of the vacuum chamber connected to the pump is placed in the one region on the one side of the vacuum chamber on which the substrate is absent, and where the pressure-regulating valve for controlling the vacuum chamber to a specified pressure is an up-and-down valve disposed directly under the substrate electrode and just over the turbo-molecular pump, the pressure-regulating valve being placed in the region on the one side of the two-region-separated vacuum chamber on which the substrate is absent. Furthermore, the present invention is effective in the case where, as shown in FIG. 20, the turbo-molecular pump 3 is not placed just under the substrate electrode 6, neither is the pressure-regulating valve 17 placed just under the substrate electrode 6, the pressure-regulating valve 17 being other than an up-and-down valve.

Further, the present invention has been described on a case where the internal pressure of the vacuum chamber is 0.3 Pa as one example. However, since plasma in the downstream becomes more likely to occur the more with the lower internal pressure of the vacuum chamber, the present invention is a method effective for cases where the internal pressure of the vacuum chamber is not higher than 10 Pa. Furthermore, the present invention is a method effective particularly for cases where the internal pressure of the vacuum chamber is not higher than 1 Pa.

Also, the present invention has been described on a case where the frequency of the high-frequency power to be applied on the antenna is 100 MHz as one example. However, for the plasma processing under low pressure, high-frequency power of 100 kHz to 3 GHz can be used, to all the region of which the present invention is effective. Yet, the higher the frequency of the high-frequency power, the wider the range to which the electromagnetic waves tend to spread, making the plasma generation in the downstream more likely to occur. Therefore, the present invention is a method effective for cases where the frequency of the high-frequency power is high, in particular, 50 MHz to 3 GHz.

Also, the third embodiment of the present invention has been described on a case where the width “p” of the voids between the multiplicity of conductor thin plates is 2.8 mm. In this connection, the width “p” of voids between the multiplicity of conductor thin plates needs to be sufficiently smaller than the wavelength of electromagnetic waves in order to suppress the transmission of electromagnetic waves. For prevention of leakage of electromagnetic waves in the air, a conductive punching metal plate or conductive mesh plate in which the hole pitch is smaller than about 0.03 time the wavelength (=c/f) of electromagnetic waves in the vacuum allows enough shielding effects to be obtained. However, considerations must be given to a special phenomenon that induction of electric discharge occurs in the plasma due to the transmission of the charged particles in addition to the leakage of electromagnetic waves. According to our experiments, it has been known that if the width of voids between the multiplicity of conductor thin plates is “p,” the frequency of the high-frequency power to be applied to the antenna is “f” and the light velocity is “c,” then satisfying a relational expression of

p<0.003×c/f

makes it possible to suppress the plasma generation in the downstream over quite a wide range of discharge conditions. For more positive suppression of plasma generation in the downstream, however, if the width of voids between the multiplicity of conductor thin plates is “p,” the frequency of the high-frequency power to be applied to the antenna is “f” and the light velocity is “c,” then it is desirable to satisfy a relational expression of

p<0.001×c/f.

Further, the fourth embodiment of the present invention has been described on a case where the width “p” of voids between the multiplicity of conductor bars is 8 mm. However, for the suppression of transmission of electromagnetic waves, the width “p” of voids between the multiplicity of conductor bars needs to be sufficiently smaller than the wavelength of electromagnetic waves. For prevention of leakage of electromagnetic waves in the air, a conductive punching metal plate or conductive mesh plate in which the hole pitch is smaller than about 0.03 time the wavelength (=c/f) of electromagnetic waves in the vacuum allows enough shielding effects to be obtained. However, considerations must be given to a special phenomenon that induction of electric discharge occurs in the plasma due to the transmission of the charged particles in addition to the leakage of electromagnetic waves. According to our experiments, it has been known that if the width of voids between the multiplicity of conductor bars is “p,” the frequency of the high-frequency power to be applied to the antenna is “f” and the light velocity is “c,” then satisfying a relational expression of

p<0.01×c/f

makes it possible to suppress the plasma generation in the downstream over quite a wide range of discharge conditions. For more positive suppression of plasma generation in the downstream, however, if the width of voids between the multiplicity of conductor bars is “p,” the frequency of the high-frequency power to be applied to the antenna is “f” and the light velocity is “c,” then it is desirable to satisfy a relational expression of

p<0.003×c/f.

Further, the above third and fourth embodiments of the present invention have been described on a case where the inner chamber-forming member covers the inner wall surface of the vacuum chamber and the downstream side of the opening of the inner chamber-forming member is grounded so that electromagnetic waves do not leak through the opening to the region on the side of the vacuum chamber on which the substrate is absent, the vacuum chamber being separated into the two regions. With such a structure, plasma generation in the downstream can be prevented more effectively. In some cases where the power is not higher than 500 W, however, plasma generation in the downstream can be prevented without such a structure.

As apparent from the above description, according to the fifth aspect of the present invention, there is provided a plasma processing method for generating plasma within a grounded vacuum chamber and processing a substrate placed on a substrate electrode within the vacuum chamber, the plasma being generated by applying a high-frequency power having a frequency of 100 kHz to 3 GHz to an antenna provided opposite to the substrate while interior of the vacuum chamber is controlled to a specified pressure by supplying a gas into the vacuum chamber and simultaneously exhausting the interior of the vacuum chamber, wherein the vacuum chamber is separated into a region on one side on which the substrate is present and a region on the other side on which the substrate is absent by a shielding plate comprised of a multiplicity of conductor thin plates and grounded at nearly all their peripheral portions and extending radially from the substrate electrode toward the inner wall surface of the vacuum chamber, in which arrangement with gas exhausted from the region on the substrate-present side to the region on the substrate-absent side through the voids between the multiplicity of conductor thin plates, the substrate is processed in the state that plasma has not sneaked up to the region on the side on which the substrate is absent. Therefore, a plasma processing method which is good at power efficiency and capable of reducing the maintenance work can be realized.

Also, according to the sixth aspect of the present invention, there is provided a plasma processing method for generating plasma within a grounded vacuum chamber and processing a substrate placed on a substrate electrode within the vacuum chamber, the plasma being generated by applying a high-frequency power having a frequency of 100 kHz to 3 GHz to an antenna provided opposite to the substrate while interior of the vacuum chamber is controlled to a specified pressure by supplying a gas into the vacuum chamber and simultaneously exhausting the interior of the vacuum chamber, wherein the vacuum chamber is separated into a region on one side on which the substrate is present and a region on the other side on which the substrate is absent by a shielding plate comprised of a multiplicity of conductor bars and grounded at nearly all their peripheral portions and extending radially from the substrate electrode toward the inner wall surface of the vacuum chamber, in which arrangement with gas exhausted from the region on the substrate-present side to the region on the substrate-absent side through the voids between the multiplicity of conductor bars, in which arrangement the substrate is processed in the state that plasma has not sneaked up to the region on the side on which the substrate is absent. Therefore, a plasma processing method which is good at power efficiency and capable of reducing the maintenance work can be realized.

Also, according to the seventh aspect of the present invention, there is provided a plasma processing apparatus comprising: a grounded vacuum chamber; a gas supply unit for supplying gas into the vacuum chamber; an exhausting unit for exhausting interior of the vacuum chamber; a pressure-regulating valve for controlling the interior of the vacuum chamber to a specified pressure; a substrate electrode for on which a substrate is placed within the vacuum chamber; an antenna provided opposite to the substrate electrode; and high-frequency power supply capable of applying a high-frequency power having a frequency of 100 kHz to 3 GHz to the antenna, wherein the vacuum chamber is separated into a region on one side on which the substrate is present and a region on the other side on which the substrate is absent by a shielding plate comprised of a multiplicity of conductor thin plates and grounded at nearly all their peripheral portions and extending radially from the substrate electrode toward the inner wall surface of the vacuum chamber. Therefore, a plasma processing apparatus which is less liable to occurrence of plasma spread to the region downstream of the substrate electrode, good at power efficiency, and capable of reducing the maintenance work can be realized.

Also, according to the eighth aspect of the present invention, there is provided a plasma processing apparatus comprising: a grounded vacuum chamber; a gas supply unit for supplying gas into the vacuum chamber; an exhausting unit for exhausting interior of the vacuum chamber; a pressure-regulating valve for controlling the interior of the vacuum chamber to a specified pressure; a substrate electrode on which a substrate is placed within the vacuum chamber; an antenna provided opposite to the substrate electrode; and high-frequency power supply capable of applying a high-frequency power having a frequency of 100 kHz to 3 GHz to the antenna, wherein the vacuum chamber is separated into a region on one side on which the substrate is present and a region on the other side on which the substrate is absent by a shielding plate comprised of a multiplicity of conductor bars and grounded at nearly all their peripheral portions and extending radially from the substrate electrode toward the inner wall surface of the vacuum chamber. Therefore, a plasma processing apparatus which is less liable to occurrence of plasma spread to the region downstream of the substrate electrode, good at power efficiency, and capable of reducing the maintenance work can be realized.

Although the present invention has been fully described in connection with the preferred embodiments thereof with reference to the accompanying drawings, it is to be noted that various changes and modifications are apparent to those skilled in the art. Such changes and modifications are to be understood as included within the scope of the present invention as defined by the appended claims unless they depart therefrom.

What is claimed is:

1. A plasma processing method for generating plasma within a grounded vacuum chamber and processing a substrate placed on a substrate electrode within the vacuum chamber, the plasma being generated by applying a high-frequency power having a frequency of 100 kHz to 3 GHz to an antenna provided opposite to the substrate while interior of the vacuum chamber is controlled to a pressure by supplying a gas into the vacuum chamber and simultaneously exhausting the interior of the vacuum chamber, the method comprising:
in a state that the vacuum chamber is separated into a region on one side on which the substrate is present and a region on the other side on which the substrate is absent by a plurality of layers of porous conductor which are grounded at nearly all of their outer peripheral portions, processing the substrate under a condition that plasma has not reached the region on the side on which the substrate is absent.

2. A plasma processing method for generating plasma within a grounded vacuum chamber and processing a substrate placed on a substrate electrode within the vacuum chamber, the plasma being generated by applying a high-frequency power having a frequency of 100 kHz to 3 GHz to an antenna provided opposite to the substrate while interior of the vacuum chamber is controlled to a pressure by supplying a gas into the vacuum chamber and simultaneously exhausting the interior of the vacuum chamber, the method comprising:
in a state that the vacuum chamber is separated into a region on one side on which the substrate is present and a region on the other side on which the substrate is absent by a porous conductor which is grounded at nearly all of its outer peripheral portion as well as a porous wave absorber for absorbing waves, processing the substrate under a condition that plasma has not reached the region on the side on which the substrate is absent.

3. A plasma processing apparatus comprising:
a gas supply unit for supplying gas into a grounded vacuum chamber;
an exhausting unit for exhausting interior of the vacuum chamber;
a pressure-regulating valve for controlling the interior of the vacuum chamber to a pressure;
a substrate electrode on which a substrate is placed within the vacuum chamber;
an antenna provided opposite to the substrate electrode;
high-frequency power supply capable of supplying a high-frequency power having a frequency of 100 kHz to 3 GHz to the antenna; and
a plurality of layers of porous conductor which are grounded at nearly all of their outer peripheral portions and arranged so that the vacuum chamber is separated into a region on one side on which the substrate is present and a region on the other side on which the substrate is absent by the plurality of layers of porous conductor.

4. A plasma processing apparatus according to claim 3, further comprising a turbo-molecular pump for exhausting the vacuum chamber which is disposed just under the substrate electrode, an exhaust port of the vacuum chamber connected to the turbo-molecular pump being placed in the region on the substrate-absent side of the vacuum chamber separated into the two regions.

5. A plasma processing apparatus according to claim 4, wherein the pressure-regulating valve for controlling the vacuum chamber to the pressure is an up-and-down valve placed directly under the substrate electrode and just over the turbo-molecular pump, the pressure-regulating valve being placed in the region on the substrate-absent side of the vacuum chamber separated into the two regions.

6. A plasma processing apparatus according to claim 3, wherein frequency of the high-frequency power applied to the antenna is within a range of 50 MHz to 3 GHz.

7. A plasma processing apparatus according to claim 3, wherein an inner wall surface of the vacuum chamber is covered with an inner chamber-forming member, and one side of the inner chamber-forming member downstream of its opening portion is grounded so that electromagnetic waves do not leak to the region on the substrate-absent side of the vacuum chamber separated into the two regions through a gap between the inner chamber-forming member and the inner wall surface of the vacuum chamber.

8. A plasma processing apparatus according to claim 3, wherein distance between the plurality of layers of porous conductor is within a range of 3 mm to 20 mm.

9. A plasma processing apparatus according to claim 3, wherein porosity per unit area of the plurality of layers of porous conductor is not less than 50% each.

10. A plasma processing apparatus comprising:
a gas supply unit for supplying gas into a grounded vacuum chamber;
an exhausting unit for exhausting interior of the vacuum chamber;
a pressure-regulating valve for controlling the interior of the vacuum chamber to a pressure;
a substrate electrode on which a substrate is placed within the vacuum chamber;
an antenna provided opposite to the substrate electrode;
high-frequency power supply capable of supplying a high-frequency power having a frequency of 100 kHz to 3 GHz to the antenna; and
a porous conductor which is grounded at nearly all of its outer peripheral portion, and a porous wave absorber by both of which the vacuum chamber is separated into a region on one side on which the substrate is present and a region on the other side on which the substrate is absent.

11. A plasma processing apparatus according to claim 10, wherein the porous conductor faces the region on the substrate-present side of the vacuum chamber separated into the two regions while the porous wave absorber faces the region on the substrate-absent side of the vacuum chamber separated into the two regions.

12. A plasma processing apparatus according to claim 10, further comprising a turbo-molecular pump for exhausting the vacuum chamber which is disposed just under the substrate electrode, an exhaust port of the chamber connected to the turbo-molecular pump being placed in the region on the substrate-absent side of the vacuum chamber separated into the two regions.

13. A plasma processing apparatus according to claim 12, wherein the pressure-regulating valve for controlling the vacuum chamber to the pressure is an up-and-down valve placed directly under the substrate electrode and just over the turbo-molecular pump, the pressure-regulating valve being placed in the region on the substrate-absent side of the vacuum chamber separated into the two regions.

14. A plasma processing apparatus according to claim 10, wherein frequency of the high-frequency power applied to the antenna is within a range of 50 MHz to 3 GHz.

15. A plasma processing apparatus according to claim 10, wherein an inner wall surface of the vacuum chamber is covered with an inner chamber-forming member, and one side of the inner chamber-forming member downstream of its opening portion is grounded so that electromagnetic waves do not leak to the region on the substrate-absent side of the vacuum chamber separated into the two regions through a gap between the inner chamber-forming member and the inner wall surface of the vacuum chamber.

16. A plasma processing apparatus according to claim 10, wherein distance between the porous conductor and the porous wave absorber is within a range of 3 mm to 20 mm.

17. A plasma processing apparatus according to claim 10, wherein porosities per unit area of the porous conductor and the porous wave absorber are not less than 50% each.

18. A plasma processing method for generating plasma within a grounded vacuum chamber and processing a substrate placed on a substrate electrode within the vacuum chamber, the plasma being generated by applying a high-frequency power having a frequency of 100 kHz to 3 GHz to an antenna provided opposite to the substrate while interior of the vacuum chamber is controlled to a pressure by supplying a gas into the vacuum chamber and simultaneously exhausting the interior of the vacuum chamber, the method comprising:
in a state that the vacuum chamber is separated into a region on one side on which the substrate is present and a region on the other side on which the substrate is absent by a porous conductor which is grounded, processing the substrate under a condition that plasma has not reached the region on the side on which the substrate is absent.

19. A plasma processing method for generating plasma within a grounded vacuum chamber and processing a substrate placed on a substrate electrode within the vacuum chamber, the plasma being generated by applying a high-frequency power having a frequency of 100 kHz to 3 GHz to an antenna provided opposite to the substrate while interior of the vacuum chamber is controlled to a pressure by supplying a gas into the vacuum chamber and simultaneously exhausting the interior of the vacuum chamber, the method comprising:
in a state that the vacuum chamber is separated into a region on one side on which the substrate is present and a region on the other side on which the substrate is absent by a porous wave absorber for absorbing waves, processing the substrate under a condition that plasma has not reached the region on the side on which the substrate is absent.

20. A plasma processing method according to claim 18, wherein the substrate is processed under a condition that an inner wall surface of the vacuum chamber is covered with an inner chamber-forming member, and one side of the inner chamber-forming member downstream of its opening portion is grounded so that electromagnetic waves do not leak to the region on the substrate-absent side of the vacuum chamber separated into the two regions through the opening portion of the inner chamber-forming member.

21. A plasma processing apparatus comprising:
a gas supply unit for supplying gas into a grounded vacuum chamber;
an exhausting unit for exhausting interior of the vacuum chamber;
a pressure-regulating valve for controlling the interior of the vacuum chamber to a pressure;
a substrate electrode on which a substrate is placed within the vacuum chamber;
an antenna provided opposite to the substrate electrode;
high-frequency power supply capable of supplying a high-frequency power having a frequency of 100 kHz to 3 GHz to the antenna; and
a porous conductor which is grounded and arranged so that the vacuum chamber is separated into a region on one side on which the substrate is present and a region on the other side on which the substrate is absent by the porous conductor.

22. A plasma processing apparatus comprising:
a gas supply unit for supplying gas into a grounded vacuum chamber;
an exhausting unit for exhausting interior of the vacuum chamber;
a pressure-regulating valve for controlling the interior of the vacuum chamber to a pressure;
a substrate electrode on which a substrate is placed within the vacuum chamber;
an antenna provided opposite to the substrate electrode;
high-frequency power supply capable of supplying a high-frequency power having a frequency of 100 kHz to 3 GHz to the antenna; and
a porous wave absorber which is grounded and arranged so that the vacuum chamber is separated into a region on one side on which the substrate is present and a region on the other side on which the substrate is absent by the porous wave absorber.

23. A plasma processing apparatus according to claim 21, wherein when a hole pitch of the porous conductor is p, a frequency of the high-frequency power to be applied to the antenna is f, and a light velocity is c, a relational expression of p<0.002×c/f is satisfied.

24. A plasma processing apparatus according to claim 21, wherein when a hole pitch of the porous conductor is p, a frequency of the high-frequency power to be applied to the antenna is f, and a light velocity is c, a relational expression of
p<0.0005×c/f
is satisfied.

25. A plasma processing apparatus according to claim 22, wherein when a hole pitch of the wave absorber is p, a frequency of the high-frequency power to be applied to the antenna is f, and a light velocity is c, a relational expression of
p<0.02×c/f
is satisfied.

26. A plasma processing apparatus according to claim 22, wherein when a hole pitch of the wave absorber is p, a frequency of the high-frequency power to be applied to the antenna is f, and a light velocity is c, a relational expression of
p<0.005×c/f
is satisfied.

27. A plasma processing method for generating plasma within a grounded vacuum chamber and processing a substrate placed on a substrate electrode within the vacuum chamber, the plasma being generated by applying a high-frequency power having a frequency of 100 kHz to 3 GHz to an antenna provided opposite to the substrate while interior of the vacuum chamber is controlled to a pressure by supplying a gas into the vacuum chamber and simultaneously exhausting the interior of the vacuum chamber, the method comprising:
in a state that the vacuum chamber is separated into a region on one side on which the substrate is present and a region on the other side on which the substrate is absent by a shielding plate which is grounded and comprised of a multiplicity of conductor thin plates radially extending from the substrate electrode toward an inner wall surface of the vacuum chamber, processing the substrate under a condition that plasma has not reached the region on the side on which the substrate is absent.

28. A plasma processing method for generating plasma within a grounded vacuum chamber and processing a substrate placed on a substrate electrode within the vacuum chamber, the plasma being generated by applying a high-frequency power having a frequency of 100 kHz to 3 GHz to an antenna provided opposite to the substrate while interior of the vacuum chamber is controlled to a pressure by supplying a gas into the vacuum chamber and simultaneously exhausting the interior of the vacuum chamber, the method comprising:
in a state that the vacuum chamber is separated into a region on one side on which the substrate is present and a region on the other side on which the substrate is absent by a shielding plate which is grounded and comprised of a multiplicity of conductor bars radially extending from the substrate electrode toward an inner wall surface of the vacuum chamber, processing the substrate under a condition that plasma has not reached the region on the side on which the substrate is absent.

29. A plasma processing apparatus comprising:
a gas supply unit for supplying gas into a grounded vacuum chamber;
an exhausting unit for exhausting interior of the vacuum chamber;
a pressure-regulating valve for controlling the interior of the vacuum chamber to a pressure;
a substrate electrode on which a substrate is placed within the vacuum chamber;
an antenna provided opposite to the substrate electrode;
high-frequency power supply capable of supplying a high-frequency power having a frequency of 100 kHz to 3 GHz to the antenna; and
a shielding plate which is grounded and comprised of a multiplicity of conductor thin plates radially extending from the substrate electrode toward an inner wall surface of the vacuum chamber and arranged so that the vacuum chamber is separated into a region on one side on which the substrate is present and a region on the other side on which the substrate is absent by the shielding plate.

30. A plasma processing apparatus comprising:
a gas supply unit for supplying gas into a grounded vacuum chamber;
an exhausting unit for exhausting interior of the vacuum chamber;
a pressure-regulating valve for controlling the interior of the vacuum chamber to a pressure;
a substrate electrode on which a substrate is placed within the vacuum chamber;
an antenna provided opposite to the substrate electrode;
high-frequency power supply capable of supplying a high-frequency power having a frequency of 100 kHz to 3 GHz to the antenna; and
a shielding plate which is grounded and comprised of a multiplicity of conductor bars radially extending from the substrate electrode toward an inner wall surface of the vacuum chamber and arranged so that the vacuum chamber is separated into a region on one side on which the substrate is present and a region on the other side on which the substrate is absent by the shielding plate.

31. A plasma processing apparatus according to claim 29, wherein when a width of void between the multiplicity of conductor thin plates is p, a frequency of the high-frequency power to be applied to the antenna is f, and a light velocity is c, a relational expression of
p<0.003×c/f
is satisfied.

32. A plasma processing apparatus according to claim 29, wherein when a width of void between the multiplicity of conductor thin plates is p, a frequency of the high-frequency power to be applied to the antenna is f, and a light velocity is c, a relational expression of
p<0.001×c/f
is satisfied.

33. A plasma processing apparatus according to claim 30, wherein when a width of void between the multiplicity of conductor bars is p, a frequency of the high-frequency power to be applied to the antenna is f, and a light velocity is c, a relational expression of
p<0.01×c/f
is satisfied.

34. A plasma processing apparatus according to claim 30, wherein when a width of void between the multiplicity of conductor bars is p, a frequency of the high-frequency power to be applied to the antenna is f, and a light velocity is c, a relational expression of
p<0.003×c/f
is satisfied.
